(19) United States
(12) Patent Application Publication
(10) Pub. No.: US 2024/0412687 A1
(43) Pub. Date: Dec. 12, 2024

(54) DISPLAY APPARATUS AND ELECTRONIC DEVICE INCLUDING THE DISPLAY APPARATUS

(71) Applicant: Semiconductor Energy Laboratory Co., Ltd., Atsugi-shi, Kanagawa-ken (JP)

(72) Inventors: Koji KUSUNOKI, Isehara (JP); Tomoaki ATSUMI, Hadano (JP); Hideaki SHISHIDO, Atsugi (JP); Susumu KAWASHIMA, Atsugi (JP)

(21) Appl. No.: 18/695,921

(22) PCT Filed: Oct. 3, 2022
(86) PCT No.: PCT/IB2022/059393

§ 371 Date: Mar. 27, 2024

(30) Foreign Application Priority Data
Oct. 15, 2021 (JP) 2021-169360
Oct. 22, 2021 (JP) 2021-172835

(51) Int. Cl. G09G 3/3233; G09G 3/3266; H10K 59/127; H10K 59/131; H10K 59/35

(52) U.S. Cl. CPC G09G 3/3233; G09G 3/3266; H10K 59/1275; H10K 59/131; G09G 2300/0842; G09G 2310/0286; G09G 2310/04; G09G 2310/08; G09G 2320/0261; G09G 2330/021; G09G 2340/0435; H10K 59/35

(57) ABSTRACT

A display apparatus with a novel structure is provided. The display apparatus includes a display portion where a first transistor and a display element are provided to be stacked. The display portion includes a first sub-display portion and a second sub-display portion. The first sub-display portion and the second sub-display portion each include a plurality of pixel circuits each controlling the display element and a gate line driver circuit outputting a signal for driving the plurality of pixel circuits. The gate line driver circuit and the plurality of pixel circuits each include a first transistor. In the display portion, the number of image rewriting times per unit time for image data in the first sub-display portion is smaller than the number of image rewriting times per unit time for image data in the second sub-display portion.

### TECHNICAL FIELD

This specification describes a display apparatus, an electronic device including the display apparatus, and the like.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof.

### BACKGROUND ART

Display apparatuses have been used in a variety of electronic devices, e.g., portable information terminals such as smartphones, television devices, and HMDs (Head Mounted Displays) suitable for applications such as virtual reality (VR) and augmented reality (AR). A display apparatus used for an HMD or the like is required to have a narrower bezel, lower consumption, and display performance with a high refresh rate of 120 Hz or more, for example. For example, Patent Document 1 discloses an HMD that includes minute pixels by using transistors capable of high-speed driving.

### REFERENCE

### Patent Document

[Patent Document 1] Japanese Published Patent Application No. 2000-2856

### SUMMARY OF THE INVENTION

### Problems to be Solved by the Invention

In the case where a display apparatus performs display at a high refresh rate, it is desirable to use a transistor capable of high-speed switching. However, a transistor capable of high-speed switching has a large current (leakage current) flowing in an off state (also referred to as a non-conduction state), which makes it difficult to perform display at a low refresh rate. In the case where display is performed at a low refresh rate, a structure using a transistor with a small leakage current as a transistor in a pixel circuit is effective. However, in the case where the entire screen is refreshed, power consumption of driver circuits for driving the pixel circuits might be increased.

An object of one embodiment of the present invention is to provide a novel display apparatus and an electronic device or the like including the display apparatus. Another object of one embodiment of the present invention is to provide a display apparatus with a novel structure that can suppress an increase in power consumption in display at a high refresh rate and an electronic device or the like including the display apparatus. Another object of one embodiment of the present invention is to provide a well-designed display apparatus with a novel structure. Another object of one embodiment of the present invention is to provide a highly convenient display apparatus with a novel structure and an electronic device or the like including the display apparatus.

The description of a plurality of objects does not preclude the existence of each object. One embodiment of the present invention does not necessarily achieve all the objects described as examples. Furthermore, objects other than those listed are apparent from description of this specification, and such objects can be objects of one embodiment of the present invention.

### Means for Solving the Problems

One embodiment of the present invention is a display apparatus including a display portion where a first transistor and a display element are provided to be stacked. The display portion includes a first sub-display portion and a second sub-display portion. The first sub-display portion and the second sub-display portion each include a plurality of pixel circuits each controlling the display element and a gate line driver circuit outputting a signal for driving the plurality of pixel circuits. The gate line driver circuit and the plurality of pixel circuits each include the first transistor. In the display portion, the number of image rewriting times per unit time for image data in the first sub-display portion is smaller than the number of image rewriting times per unit time for image data in the second sub-display portion.

In the display apparatus of one embodiment of the present invention, the first transistor preferably includes a metal oxide in a semiconductor layer including a channel formation region.

One embodiment of the present invention is a display apparatus including a display portion where a first layer including a first transistor, a second layer including a second transistor, and a display element are provided to be stacked. The display portion includes a first sub-display portion and a second sub-display portion. The first sub-display portion and the second sub-display portion each include a plurality of pixel circuits each controlling the display element and a gate line driver circuit outputting a signal for driving the plurality of pixel circuits. The gate line driver circuit includes the first transistor and the second transistor. The plurality of pixel circuits each include the first transistor and the second transistor. In the display portion, the number of image rewriting times per unit time for image data in the first sub-display portion is smaller than the number of image rewriting times per unit time for image data in the second sub-display portion.

One embodiment of the present invention is a display apparatus including a display portion where a first layer including a first transistor, a second layer including a second transistor, and a display element are provided to be stacked. The display portion includes a first sub-display portion and a second sub-display portion. The first sub-display portion and the second sub-display portion each include a plurality of pixel circuits each controlling the display element and a gate line driver circuit outputting a signal for driving the plurality of pixel circuits. The gate line driver circuit includes the first transistor and the second transistor. The plurality of pixel circuits each include the first transistor and the second transistor. The second transistor includes a metal oxide in a semiconductor layer including a channel formation region. In the display portion, the number of image rewriting times per unit time for image data in the first sub-display portion is smaller than the number of image rewriting times per unit time for image data in the second sub-display portion.

In the display apparatus of one embodiment of the present invention, the first transistor preferably contains silicon in a semiconductor layer including a channel formation region.

In the display apparatus of one embodiment of the present invention, the first transistor preferably includes a metal oxide in a semiconductor layer including a channel formation region.

In the display apparatus of one embodiment of the present invention, a source line driver circuit is preferably provided in a region outside the display portion.

One embodiment of the present invention is a display apparatus including a display portion where a first layer including a first transistor and a display element are provided to be stacked. The display portion includes a first sub-display portion and a second sub-display portion. The first sub-display portion and the second sub-display portion are provided in different display panels. The display panels each include a pixel circuit portion and a light-transmitting region. The light-transmitting region of one of the display panels includes a region overlapping with the pixel circuit portion of the other of the display panels.

One embodiment of the present invention is an electronic device including any one of the above display apparatuses and a housing.

Note that other embodiments of the present invention will be shown in the description of the following embodiments and the drawings.

### Effect of the Invention

One embodiment of the present invention can provide a novel display apparatus and an electronic device or the like including the display apparatus. Another embodiment of the present invention can provide a display apparatus with a novel structure that can suppress an increase in power consumption in display at a high refresh rate and an electronic device or the like including the display apparatus. Another object of one embodiment of the present invention is to provide a well-designed display apparatus with a novel structure. Another embodiment of the present invention can provide a highly convenient display apparatus with a novel structure and an electronic device or the like including the display apparatus.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1A and FIG. 1B are diagrams illustrating a structure example of a display apparatus.

FIG. 2A to FIG. 2C are diagrams illustrating a structure example of a display apparatus.

FIG. 3A and FIG. 3B are diagrams illustrating a structure example of a display apparatus.

FIG. 4A to FIG. 4C are diagrams illustrating a structure example of a display apparatus.

FIG. 5A and FIG. 5B are diagrams illustrating a structure example of a display apparatus.

FIG. 6 is a diagram illustrating a structure example of a display apparatus.

FIG. 7A to FIG. 7D are circuit diagrams illustrating structure examples of a display apparatus.

FIG. 8A to FIG. 8D are circuit diagrams illustrating structure examples of a display apparatus.

FIG. 9A to FIG. 9D are circuit diagrams and a timing chart showing structure examples of a display apparatus.

FIG. 10A to FIG. 10C are circuit diagrams and a timing chart showing a structure example of a display apparatus.

FIG. 11A and FIG. 11B are a circuit diagram and a timing chart showing a structure example of a display apparatus.

FIG. 12 is a circuit diagram illustrating a structure example of a display apparatus.

FIG. 13 is a circuit diagram illustrating a structure example of a display apparatus.

FIG. 14 is a circuit diagram illustrating a structure example of a display apparatus.

FIG. 15 is a circuit diagram illustrating a structure example of a display apparatus.

FIG. 16 is a circuit diagram illustrating a structure example of a display apparatus.

FIG. 17 is a circuit diagram illustrating a structure example of a display apparatus.

FIG. 18A and FIG. 18B are diagrams illustrating a structure example of a display apparatus.

FIG. 19A and FIG. 19B are diagrams illustrating a structure example of a display apparatus.

FIG. 20 is a timing chart showing a structure example of a display apparatus.

FIG. 21 is a timing chart showing a structure example of a display apparatus.

FIG. 22 is a diagram illustrating a structure example of a display apparatus.

FIG. 23A and FIG. 23B are diagrams illustrating structure examples of a display apparatus.

FIG. 24 is a diagram illustrating a structure example of a display apparatus.

FIG. 25A to FIG. 25C are diagrams illustrating a structure example of a display apparatus.

FIG. 26A to FIG. 26C are diagrams illustrating a structure example of a display apparatus.

FIG. 27A to FIG. 27D are diagrams illustrating a structure example of a display apparatus.

FIG. 28 is a diagram illustrating a structure example of a display apparatus.

FIG. 29A and FIG. 29B are diagrams illustrating a structure example of a display apparatus.

FIG. 30 is a diagram illustrating a structure example of a display apparatus.

FIG. 31 is a diagram illustrating a structure example of a display apparatus.

FIG. 32A to FIG. 32F are diagrams illustrating structure examples of electronic devices.

FIG. 33A to FIG. 33E are diagrams illustrating structure examples of electronic devices.

FIG. 34A to FIG. 34G are diagrams illustrating structure examples of electronic devices.

FIG. 35A to FIG. 35D are diagrams illustrating structure examples of electronic devices.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the ordinal numbers do not limit the number of components. In addition, the ordinal numbers do not limit the order of components. Furthermore, in this specification and the like, for example, a “first” component in one embodiment can be referred to as a “second” component in other embodiments or the scope of claims. For another example, a “first” component in one embodiment in this specification and the like can be omitted in other embodiments or the scope of claims.

In some cases, the same components, components having similar functions, components made of the same material, components formed at the same time, and the like are denoted by the same reference numerals in the drawings and repeated description thereof is omitted.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and particularly when they need to be distinguished from each other, an identification sign such as “_1”, “_2”, “[n]”, or “[m,n]” is sometimes added to the reference numerals. For example, a second gate line GL is referred to as a gate line GL[2].

### Embodiment 1

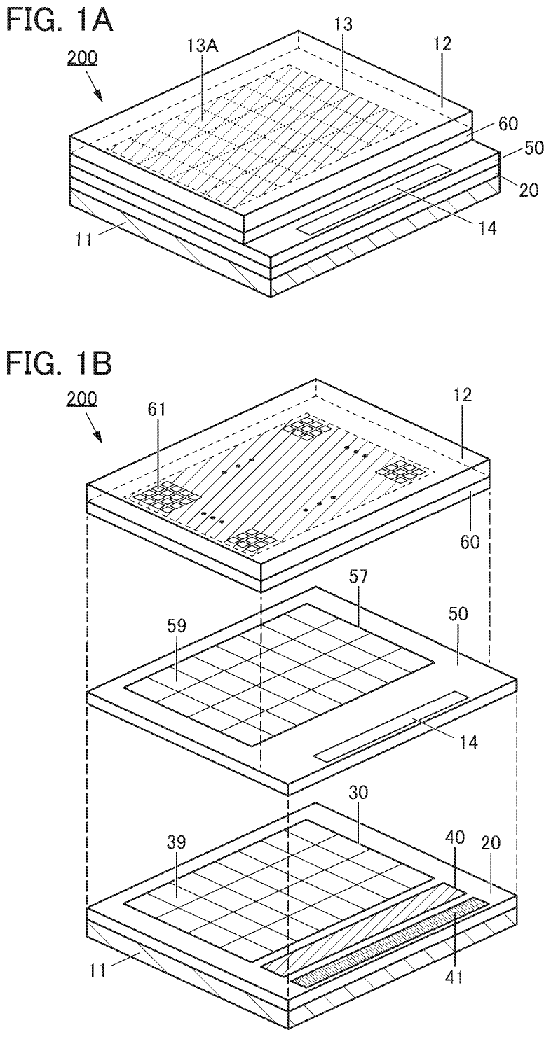

Structure examples of a display apparatus of one embodiment of the present invention will be described with reference to FIG. 1A to FIG. 22.

### 21 Structure Example 1 of Display Apparatus>

Structures of a display apparatus of one embodiment of the present invention will be described with reference to FIG. 1A and FIG. 1B. FIG. 1A and FIG. 1B are schematic perspective views of a display apparatus 200.

The display apparatus 200 includes a substrate 11 and a substrate 12. The display apparatus 200 includes a display portion 13 composed of elements provided between the substrate 11 and the substrate 12. The display portion 13 is divided into a plurality of sections, and any one of the sections is referred to as a sub-display portion 13A.

In the display apparatus 200, a layer 20, a layer 50, and a layer 60 are provided between the substrate 11 and the substrate 12. In the display apparatus 200, a variety of signals and power supply potentials are input from the outside through a terminal portion 14, so that display can be performed.

The layer 20 is provided with a plurality of gate line driver circuits for driving the display apparatus 200. In a driver circuit portion 30 provided with the plurality of gate line driver circuits, the gate line driver circuit is provided for each section 39 provided in the layer 20. The section 39 is a region corresponding to the sub-display portion 13A. The layer 20 is provided with a source line driver circuit 40 for driving the display apparatus 200 or a control circuit 41 for controlling the driver circuit portion 30 and the source line driver circuit.

The control circuit 41 may include, for example, an LVDS (Low Voltage Differential Signaling) circuit, an MIPI (Mobile Industry Processor Interface) circuit, and/or a D/A (Digital to Analog) converter circuit having a function of an interface for receiving image data or the like from the outside of the display apparatus 200. Moreover, the control circuit 41 may include a circuit for compressing and decompressing image data and/or a power supply circuit, for example.

Since the driver circuit portion 30 provided with the gate line driver circuits is placed to overlap with the display portion 13, the width of a non-display region (also referred to as a bezel) present in the periphery of the display portion of the display apparatus 200 can be extremely narrow as compared with the case where the driver circuit portion 30 and the display portion 13 are arranged side by side; thus, the display apparatus 200 can be downsized.

Placing the section 39 provided with the gate line driver circuit, the source line driver circuit 40, and the control circuit 41 to be close to each other can shorten wirings electrically connecting the circuits. As a result, charge and discharge time of a control signal for controlling each circuit becomes short, leading to a reduction in power consumption.

The layer 20 is a layer provided with a transistor included in the gate line driver circuit. The transistor provided in the layer 20 uses silicon in its semiconductor layer including a channel formation region. In particular, as the transistor provided in the layer 20, a transistor containing polycrystalline silicon in its semiconductor layer including a channel formation region (also referred to as a “Poly-Si transistor”) is used. As polycrystalline silicon, low-temperature polysilicon (LTPS) is preferably used. Note that a transistor containing LTPS in its channel formation region is also referred to as an “LTPS transistor”. When the transistor included in the layer 20 is an LTPS transistor, the substrate 11 can be a glass substrate; thus, a lower cost and a larger area of the display apparatus 200 can be achieved. Note that the substrate 11 may be a flexible substrate such as a resin film.

As the transistor provided in the layer 20, a transistor containing a metal oxide (also referred to as an oxide semiconductor) in its semiconductor layer including a channel formation region (OS transistor) may be used.

Note that the source line driver circuit 40 or the control circuit 41 may have a structure where a connector such as an FPC (Flexible Printed Circuit) or a TCP (Tape Carrier Package) is attached or a structure where an IC (integrated circuit) is directly mounted on the substrate 11 by a COG (Chip On Glass) method.

The layer 50 is provided with a plurality of pixel circuits for independently controlling a plurality of display elements provided in the layer 60. In a pixel circuit portion 57 provided with the plurality of pixel circuits, the pixel circuit is provided for each section 59 provided in the layer 50. The section 59 is a region corresponding to the sub-display portion 13A, like the section 39.

The layer 50 is a layer provided with a transistor included in the pixel circuit. An OS transistor is preferably used as the transistor provided in the layer 50. In the case where the transistor included in the layer 50 is an OS transistor, the OS transistor can be provided to overlap with a layer including another transistor such as an LTPS transistor. Providing the transistors to overlap with each other reduces the area occupied by the pixel circuit. Thus, the resolution of the display apparatus 200 can be increased. Note that a structure combining an LTPS transistor and an OS transistor is referred to as LTPO in some cases.

An OS transistor has a feature of an extremely low off-state current. Thus, it is particularly preferable to use the OS transistor as a transistor provided in the pixel circuit, in which case analog data written to the pixel circuit can be retained for a long time.

A metal oxide used for an OS transistor is a Zn oxide, a Zn—Sn oxide, a Ga—Sn oxide, an In—Ga oxide, an In—Zn oxide, an In—M—Zn oxide (M is Ti, Ga, Y, Zr, La, Ce, Nd, Sn, or Hf), or the like. The use of a metal oxide containing Ga as M for the OS transistor is particularly preferable because the electrical characteristics such as field-effect mobility of the transistor can be made excellent by adjusting a ratio of elements. In addition, an oxide containing indium and zinc may contain one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like.

The layer 60 is provided with a plurality of display elements 61. The substrate 12 over the layer 60 is preferably a substrate formed using a material having a light-transmitting property. The display element 61 can be a light-emitting device. As the light-emitting device, an organic electroluminescent element (also referred to as an organic EL element) or the like can be used, for example. However, the light-emitting device is not limited thereto, and an inorganic EL element formed of an inorganic material may be used, for example. Note that an “organic EL element” and an “inorganic EL element” are collectively referred to as an “EL element” in some cases. The light-emitting device may contain an inorganic compound such as quantum dots. For example, when used for a light-emitting layer, the quantum dots can function as a light-emitting material.

In this specification and the like, the term “element” can be replaced with the term “device” in some cases. For example, a display element and a light-emitting element can be rephrased as a display device and a light-emitting device, respectively.

Although an example where the transistor included in the pixel circuit is an OS transistors is described in one embodiment of the present invention, another structure may be employed. For example, in addition to an OS transistor, an LTPS transistor may be included as part of the transistors included in the pixel circuit.

An OS transistor uses an N-type (n-channel) metal oxide typified by an In—Ga—Zn oxide, for example, and thus can form a CMOS (Complementary Metal Oxide Semiconductor) circuit when combined with an LTPS transistor in a pixel circuit. When the pixel circuit includes a CMOS circuit, a circuit with high driving capability and low power consumption can be achieved. In addition, since an N-type (n-channel) LTPS transistor and a P-type (p-channel) LTPS transistor need not be formed separately, the process cost of the display apparatus 200 can be reduced.

Although the structure where an OS transistor or an LTPS transistor is used as the transistor included in the gate line driver circuit is described as an example, another structure may be employed. In addition to an LTPS transistor, an OS transistor may be included as the transistor included in the gate line driver circuit. In this case, an n-channel OS transistor and a p-channel LTPS transistor can be used for the gate line driver circuit to form a CMOS circuit; thus, the CMOS circuit can be achieved without using an n-channel LTPS transistor. This enables a circuit to have both a feature of high driving capability owing to the use of an LTPS transistor and a feature of low power consumption owing to a low off-state current of an OS transistor, as compared with the case where the gate line driver circuit is formed using only n-channel transistors. In addition, since an N-type (n-channel) LTPS transistor and a P-type (p-channel) LTPS transistor need not be formed separately, the process cost of the display apparatus 200 can be reduced.

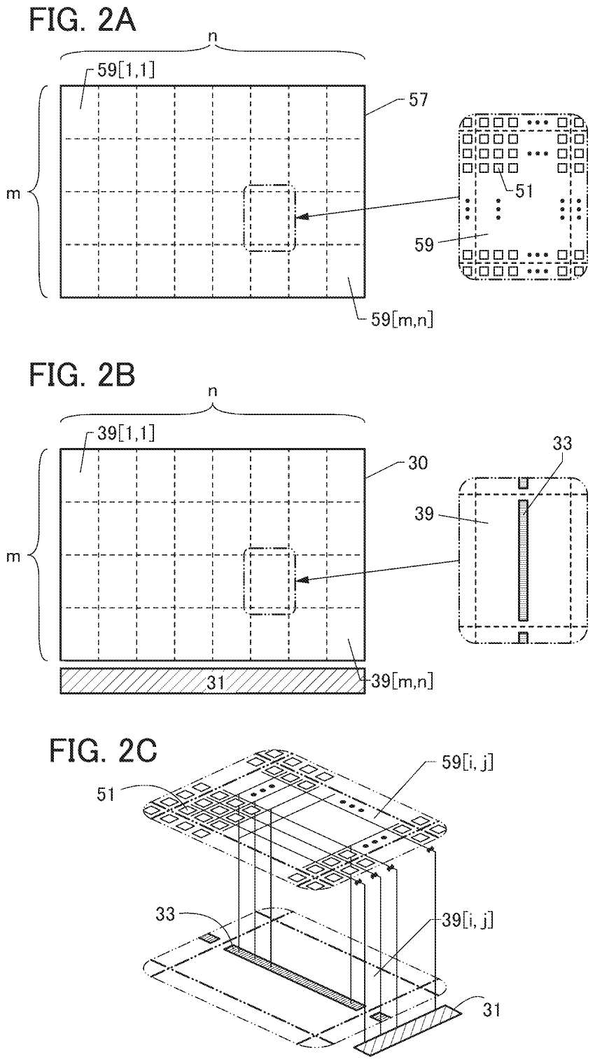

FIG. 2A illustrates a structure example of the pixel circuit portion 57 included in the display apparatus 200. FIG. 2B illustrates a structure example of the driver circuit portion 30 included in the display apparatus 200. The sections 59 and the sections 39 are each arranged in a matrix of m rows and n columns (m and n are each an integer greater than or equal to 1). In this specification and the like, the section 59 in the first row and the first column is denoted by a section 59[1,1], and the section 59 in the m-th row and the n-th column is denoted by a section 59[m,n]. Similarly, the section 39 in the first row and the first column is denoted by a section 39[1,1], and the section 39 in the m-th row and the n-th column is denoted by a section 39[m,n]. FIG. 2A and FIG. 2B illustrate a case where m is 4 and n is 8. That is, the pixel circuit portion 57 and the driver circuit portion 30 are each divided into 32 sections.

The plurality of sections 59 each include a plurality of source lines SL and a plurality of gate lines GL (not illustrated) in addition to the plurality of pixel circuits 51. In each of the plurality of sections 59, one of the plurality of pixel circuits 51 is electrically connected to at least one of the plurality of source lines SL and at least one of the plurality of gate lines GL.

One of the sections 59 and one of the sections 39 are provided to overlap with each other (see FIG. 2C). For example, a section 59[i,j] (i is an integer greater than or equal to 1 and less than or equal to m, and j is an integer greater than or equal to 1 and less than or equal to n) and a section 39[i,j] are provided to overlap with each other. The source line driver circuit 31 is electrically connected to the source lines SL included in the section 59[i,j]. A gate line driver circuit 33 included in the section 39[i,j] is electrically connected to the gate lines GL included in the section 59[i,j]. The gate line driver circuit 33 included in the section 39[i,j] has a function of controlling the plurality of pixel circuits 51 included in the section 59[i,j].

When the section 59[i,j] and the section 39[i,j] are provided to overlap with each other, a connection distance (wiring length) between the pixel circuit 51 included in the section 59[i,j] and the gate line driver circuit 33 included in the section 39[i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

The display apparatus 200 has a structure where the gate line driver circuit 33 is included in each section 39. Thus, the display portion 13 can be divided to correspond to the sections 59 and the sections 39, and image rewriting can be performed in each sub-display portion 13A. For example, in the display portion 13, image data can be rewritten only in a section with an image change and image data can be retained in a section with no change, so that power consumption can be reduced.

In this embodiment and the like, one of sections of the display portion 13 divided to correspond to the sections 59 is referred to as a sub-display portion. In the display apparatus 200 described with reference to FIG. 1A, FIG. 1B, FIG. 2A, and FIG. 2B, the display portion 13 is divided into 32 sub-display portions 13A (see FIG. 1A). The sub-display portion 13A includes a plurality of pixels each including a pixel circuit and a display element. Specifically, one sub-display portion 13A includes one section 59 including a plurality of pixel circuits 51 and a plurality of display elements 61. One section 39 has a function of controlling the potentials of the gate lines of the plurality of pixels included in one sub-display portion 13A.

In the display apparatus 200, the driving frequency (also referred to as frame frequency, frame rate, refresh rate, or the like) at the time of image display can be set freely for each sub-display portion 13A by a timing controller included in the control circuit 41. The control circuit 41 has a function of controlling operations of the plurality of sections 39 and the plurality of sections 59. In other words, the control circuit 41 has a function of controlling the driving frequency and operation timing of the plurality of sub-display portions 13A arranged in a matrix. In addition, the control circuit 41 has a function of adjusting synchronization between the sub-display portions.

Although FIG. 1A to FIG. 2C illustrate the layer 20 and the layer 50 as separate layers, the structure of one embodiment of the present invention is not limited thereto. When the transistor included in the layer 20 is an OS transistor and the transistor included in the layer 50 is an OS transistor, the transistor included in the pixel circuit and the transistor included in the gate line driver circuit can be provided in the same section.

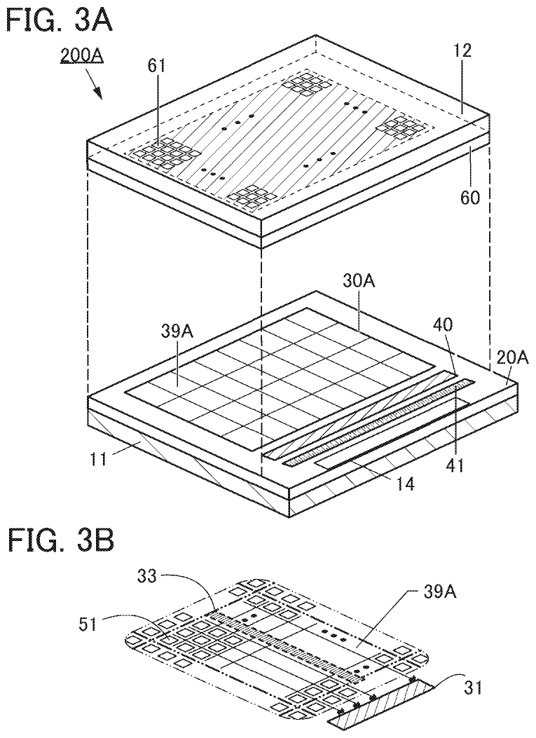

A display apparatus 200A illustrated in FIG. 3A is a structure example of a display apparatus in which the layer 20 and the layer 50 described above are in the same layer. A layer 20A is provided with a circuit portion 30A in which the driver circuit portion 30 and the pixel circuit portion 57 described above are integrated. The circuit portion 30A is provided with a section 39A corresponding to the section 39 and the section 59 described above. The section 39A is a region corresponding to the sub-display portion 13A. In addition, the layer 20A is provided with the source line driver circuit 40 for controlling the display apparatus 200A or the control circuit 41 for controlling the driver circuit portion 30 and the source line driver circuit 40.

The layer 20A is a layer provided with transistors included in the pixel circuit and the gate line driver circuit. An OS transistor is used as the transistor provided in the layer 20A. Unlike in the above-described structure where an OS transistor and an LTPS transistor are provided in different layers, a layer including an OS transistor is provided without being stacked; thus, the manufacturing cost can be reduced and the thickness of the layer including the transistors can be reduced. Note that as the OS transistors provided in the same layer, OS transistors with different characteristics can be used when difference is made in the thickness of an insulating layer or in the number of metal element atoms in a metal oxide, for example.

In the section 39A included in the layer 20A, the pixel circuits 51 and the gate line driver circuit 33 formed using OS transistors are provided as illustrated in FIG. 3B. Although FIG. 3B clearly illustrates the gate line driver circuit 33 in the section 39A, a plurality of transistors included in the gate line driver circuit 33 are preferably placed in a dispersed manner in the section 39A provided with the pixel circuits 51.

The display apparatus of one embodiment of the present invention can have lower power consumption by stacking the pixel circuits and the driver circuits and making the driving frequency different between the sub-display portions 13A. For example, the driving frequency is made different between the sub-display portions 13A in accordance with the movement of a gaze. Note that information on the movement of a gaze (a gaze point G), for example, may be obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like.

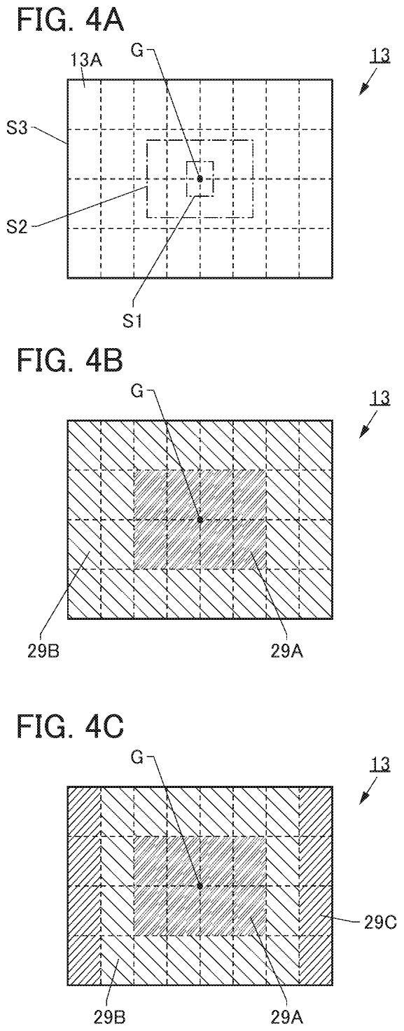

FIG. 4A illustrates the display portion 13 including the sub-display portions 13A in four rows and eight columns. FIG. 4A also illustrates a first region S1 to a third region S3 with the gaze point G as a center. In the display apparatus 200, the plurality of sub-display portions 13A are divided between a first section 29A overlapping with the first region S1 or the second region S2 and a second section 29B overlapping with the third region S3. That is, in the display apparatus 200, the plurality of sub-display portions 13A are divided between the first section 29A and the second section 29B. In this case, the first section 29A overlapping with the first region S1 and the second region S2 corresponds to sub-display portions including a region overlapping with the gaze point G, and the second section 29B corresponds to sub-display portions positioned outside the first section 29A and positioned away from the user's gaze point G (see FIG. 4B).

The operation of the gate line driver circuit included in each of the plurality of sub-display portions 13A is controlled by the control circuit 41. For example, the sub-display portion corresponding to the second section 29B is a section overlapping with the third region S3 including the stable visual field, the inducting visual field, and the supplementary visual field, and is hard for the user to discriminate. Thus, the user perceives a small reduction in practical display quality (hereinafter also referred to as “practical display quality”) even when the number of times of image data rewriting per unit time (hereinafter also referred to as “image rewriting frequency”) in displaying an image is smaller in the sub-display portion belonging to the second section 29B than in the sub-pixel portion corresponding to the first section 29A. That is, even when the driving frequency of the sub-display portion corresponding to the second section 29B is lower than the driving frequency of the sub-display portion corresponding to the first section 29A, a reduction in practical display quality is small.

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the driving frequency of the sub-display portion corresponding to the second section 29B is lower than the driving frequency of the sub-display portion corresponding to the first section 29A; thus, power consumption can be reduced in a section where the visibility by the user is low and the reduction in practical display quality can be inhibited. According to one embodiment of the present invention, both display quality maintenance and a reduction in power consumption can be achieved.

The driving frequency of the sub-display portion corresponding to the first section 29A can be higher than or equal to 30 Hz and lower than or equal to 500 Hz, preferably higher than or equal to 60 Hz and lower than or equal to 500 Hz. The driving frequency of the sub-display portion corresponding to the second section 29B is preferably lower than or equal to the driving frequency of the first section 29A, further preferably lower than or equal to half of the driving frequency of the sub-display portion corresponding to the first section 29A, still further preferably lower than or equal to one-fifth of the driving frequency of the sub-display portion corresponding to the first section 29A.

Furthermore, among the sub-display portions corresponding to the third region S3, the sub-display portions in an outer region of the second section 29B may be set to a third section 29C (see FIG. 4C), and the driving frequency of the sub-display portion corresponding to the third section 29C may be set lower than that of the sub-display portion corresponding to the second section 29B. The driving frequency of the sub-display portion corresponding to the third section 29C is preferably lower than or equal to the driving frequency of the sub-display portion corresponding to the second section 29B, further preferably lower than or equal to half of the driving frequency of the sub-display portion corresponding to the second section 29B, still further preferably lower than or equal to one-fifth of the driving frequency of the sub-display portion corresponding to the second section 29B. By significantly lowering image rewriting frequency, power consumption can be further reduced. Note that image data rewriting may be stopped if necessary. By stopping image data rewriting, power consumption can be further reduced.

In the case where such a driving method is employed, a transistor with an extremely low off-state current is suitably used as a transistor included in the pixel circuit 51. For example, an OS transistor is suitable as the transistor included in the pixel circuit 51. Since an OS transistor has an extremely low off-state current, image data supplied to the pixel circuit 51 can be retained for a long time when output of an output signal from the gate line driver circuit is stopped.

In some cases, an image whose brightness, contrast, color tone, or the like is greatly different from that of the previous image is displayed as in the case where a video scene displayed on the display portion 13 is changed, for example. In such a case, a mismatch of image switching timing is caused between the first section 29A and a section with a lower driving frequency than the first section 29A, which might cause a great difference in the brightness, contrast, color tone, or the like between the sections, leading to the loss of the practical display quality. In such a case where a video scene is changed, image rewriting can be temporarily performed in the section other than the first section 29A at the same driving frequency as the first section 29A, and then the driving frequency of the section other than the first section 29A can be decreased.

Furthermore, in the case where the fluctuation amount of the gaze point G is judged to be larger than a certain amount, image rewriting may be performed in the sub-display portion other than the sub-display portion corresponding to the first section 29A at the same driving frequency as the sub-display portion corresponding to the first section 29A, and the driving frequency of the sub-display portion other than the sub-display portion corresponding to the first section 29A may be decreased when the fluctuation amount is judged to be within the certain amount. In the case where the fluctuation amount of the gaze point G is judged to be small, the driving frequency of the sub-display portion other than the sub-display portion corresponding to the first section 29A may be further decreased.

Note that the sections corresponding to the sub-display portions included in the display portion 13 are not limited to the following three: the first section 29A, the second section 29B, and the third section 29C. Four or more sections may be set for the display portion 13. When a plurality of sections are set for the display portion 13 and the driving frequencies of the sections are gradually decreased, a reduction in practical display quality can be smaller.

When image data rewriting performed in each of the sub-display portions 13A is performed concurrently in all of the sub-display portions 13A, high-speed rewriting can be achieved. In other words, when image data rewriting performed in each of the sections 39 is performed concurrently in all of the sections 39, high-speed rewriting can be achieved.

In addition, the display portion 13 of the display apparatus 200 described as an example in this embodiment is divided into eight parts in the column direction; thus, the length of the gate line GL electrically connecting the gate line driver circuit and the pixel circuit becomes one-eighth. Accordingly, each of the resistance value and parasitic capacitance of the gate line GL becomes one-eighth, whereby degradation and delay of a signal can be inhibited and the time for rewriting image data can be easily ensured.

According to the display apparatus 200 of one embodiment of the present invention, time for writing image data can be short, and thus high-speed rewriting of a display image can be achieved. Thus, a display apparatus with high display quality can be achieved. In particular, a display apparatus that excels in displaying a moving image can be achieved.

Furthermore, according to the display apparatus 200 of one embodiment of the present invention, an output signal output from the gate line driver circuit can be controlled independently in each sub-display portion 13A; thus, the shapes or sizes of the sub-display portions 13A can be made different from each other. That is, the display portion 13 can be composed of the sub-display portions with different shapes or sizes. Thus, not only the display portion 13 with a rectangular shape but also a well-designed display portion with a circular shape or the like can be obtained.

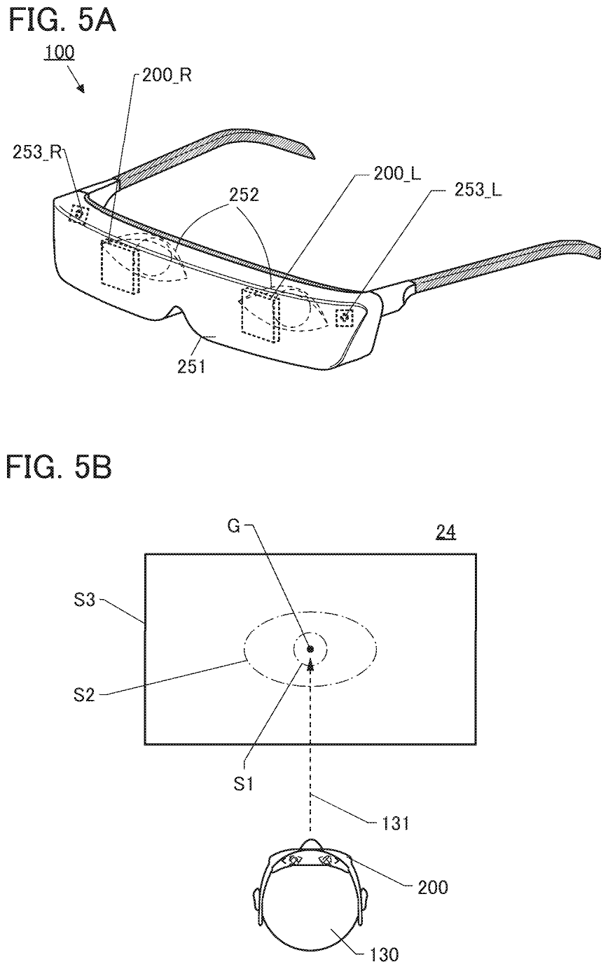

FIG. 5A is a diagram illustrating a structure example where the display apparatus 200 described with reference to FIG. 1A to FIG. 4C is used for an electronic device that is a type of a head-mounted display (HMD) and the movement of a gaze is detected. FIG. 5A is a perspective view illustrating an electronic device 100 that is a type of an HMD.

The electronic device 100 illustrated in FIG. 5A includes a pair of display apparatuses 200_L and 200_R in a housing 251. In addition, FIG. 5A illustrates eyes 252 of a user wearing the electronic device 100. FIG. 5A also illustrates a pair of imaging devices 253_L and 253_R for capturing images of the eyes 252 of the user. The imaging devices 253_L and 253_R can capture images of the movement of the periphery of the eyeballs, such as the eyelids, the glabella, and the inner and outer corners of the eyes, in addition to the eyes 252 of the user. As illustrated in FIG. 5A, the pair of imaging devices 253_L and 253_R are placed at the positions where images of the eyes 252 are captured, for example. Note that when the housing 251 is provided with an acceleration sensor such as a gyroscope sensor, the orientation of the user's head can be sensed and an image corresponding to the orientation can be displayed.

Like the above-described display apparatus 200, the display apparatuses 200_L and 200_R illustrated in FIG. 5A can have a structure where the pixel circuit portion 57 and the driver circuit portion 30 are stacked, and thus can have an extremely high pixel aperture ratio (effective display area ratio). For example, the pixel aperture ratio can be higher than or equal to 40% and lower than 100%, preferably higher than or equal to 50% and lower than or equal to 95%, further preferably higher than or equal to 60% and lower than or equal to 95%.

The display apparatuses 200_L and 200_R can have an extremely high resolution, and thus are suitable for a VR device such as an electronic device that is a type of a head-mounted display or a glasses-type AR device. For example, even in the case of a structure where the display portion of the display apparatus 200 is seen through an optical member such as a lens, pixels of the extremely-high-resolution display portion included in the display apparatus 200 are not perceived when the display portion is magnified by the lens, so that display providing a high sense of immersion can be performed.

Note that in the case where the display apparatus 200 is used as a wearable display apparatus for VR or AR, the display portion can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion may have a diagonal size of 1.5 inches or approximately 1.5 inches. When the display portion has a diagonal size less than or equal to 2.0 inches, preferably, approximately 1.5 inches, the number of times of light exposure treatment using a light exposure apparatus (typified by a scanner apparatus) can be one; thus, the productivity of a manufacturing process can be improved.

FIG. 5B illustrates a state where a user 130 wearing the electronic device 100 illustrated in FIG. 5A sees an image 24 in the direction of a gaze 131. FIG. 5B illustrates the first region S1 including the gaze point G, the second region S2 adjacent to the first region S1, and the third region S3 outside the second region.

In general, the human visual field is roughly classified into the following five fields, although varying between individuals. The discrimination visual field refers to a region within approximately 5° from the center of vision including a gaze point, where visual performance such as eyesight and color identification is the most excellent. The effective visual field refers to a region that is horizontally within approximately 30° and vertically within approximately 20° from the center of vision (a gaze point) and adjacent to the outside of the discrimination visual field, where instant identification of particular information is possible only with an eye movement. The stable visual field refers to a region that is horizontally within approximately 90° and vertically within approximately 70° from the center of vision and adjacent to the outside of the effective visual field, where identification of particular information is possible with a head movement without any difficulty. The inducting visual field refers to a region that is horizontally within approximately 100° and vertically within approximately 85° from the center of vision and adjacent to the outside of the stable visual field, where the existence of a particular target can be sensed but the identification ability is low. The supplementary visual field refers to a region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

From the above, it is found that the image quality in the discrimination visual field and the effective visual field is important in the image 24. The image quality in the discrimination visual field is particularly important.

When the gaze 131 of the user 130 moves, the gaze point G also moves. Accordingly, the first region S1 and the second region S2 also move. For example, in the case where the fluctuation amount of the gaze 131 is larger than a certain amount, it is judged that the gaze 131 is moving. That is, in the case where the fluctuation amount of the gaze 131 is larger than a certain amount, it is judged that the gaze point G is moving. Furthermore, in the case where the fluctuation amount of the gaze 131 becomes smaller than or equal to the certain amount, it is judged that the gaze 131 has stopped moving, and the first region S1 to the third region S3 are determined. That is, in the case where the fluctuation amount of the gaze point G becomes smaller than or equal to the certain amount, it is judged that the gaze point G has stopped moving, and the first region S1 to the third region S3 can be determined.

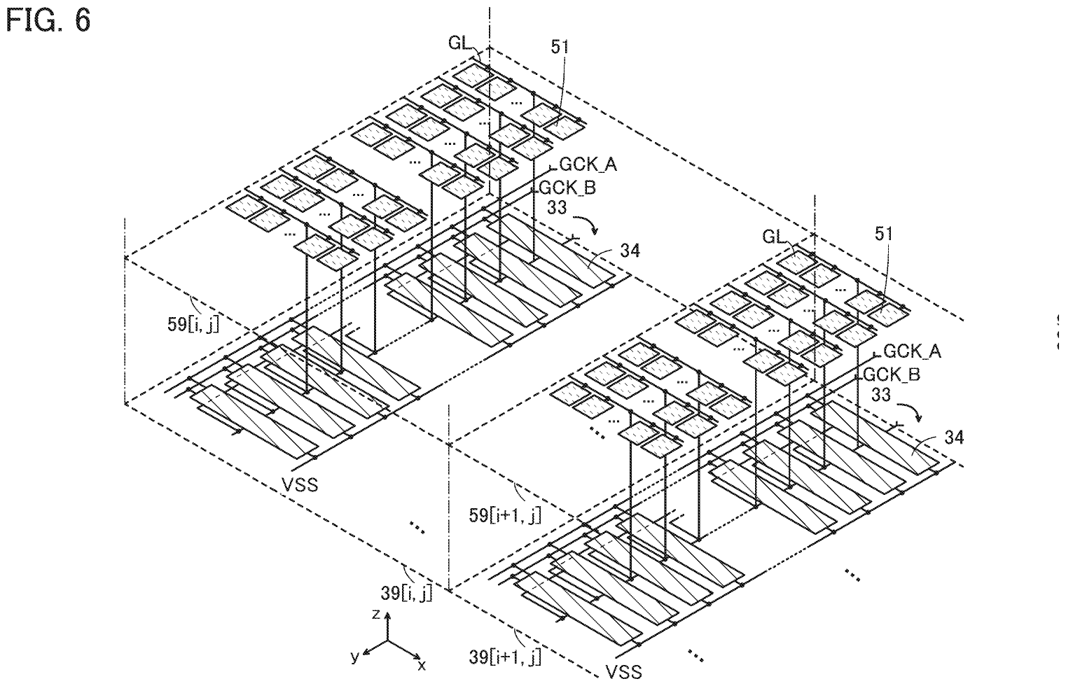

FIG. 6 is a schematic view for describing a structure of adjacent pixel circuits 51 and adjacent gate line driver circuits 33 in the sub-display portions where the sections 39 and the sections 59 are stacked in the display apparatus 200. Note that FIG. 6 illustrates the sections 39[i,j] and 39[i+1,j] and the sections 59[i,j] and 59[i+1,j] as adjacent sections.

In FIG. 6, the x direction, the y direction, and the z direction are shown. The x direction is a direction parallel to the gate line GL as illustrated in FIG. 6. The y direction is a direction parallel to the source line (not illustrated). The z direction is a direction perpendicular to a plane defined by the x direction and the y direction as illustrated in FIG. 6. That is, FIG. 6 illustrates a state where the pixel circuits 51 and the gate line driver circuits 33 are provided on the xy plane and the sections 39 and the sections 59 are stacked in the z direction. The structure illustrated in FIG. 6 is an example, and part of the pixel circuit 51 or part of the gate line driver circuit 33 may be provided in a section of the upper layer or the lower layer.

The gate line driver circuits 33 provided in the section 39[i,j] and the section 59[i+1,j] each include a plurality of pulse output circuits 34. The pulse output circuit 34 outputs a signal for selecting the pixel circuits 51 provided in the x direction at a time, through the gate line GL extending in the z direction. When the gate line driver circuit 33 is placed in a layer below the pixel circuit 51, the design flexibility can be increased; for example, the bezel can be narrowed.

Although the gate line driver circuit 33 in the section 39[i,j] and that in the section 39[i+1,j] are provided with the same number of pulse output circuits 34 in the illustrated structure, the number of pulse output circuits 34 may be different from each other. When the number of pulse output circuits 34 included in the gate line driver circuit 33 is different between the section 39[i,j] and the section 39[i+1,j], the number of pixels can be different in the y direction. Thus, the shape flexibility of the display portion can be increased. Accordingly, the display portion 13 including the sub-display portions 13A corresponding to the section 39[i,j] and the section 39[i+1,j] can be a well-designed display portion.

### <Structure Examples of Pixel Circuit>

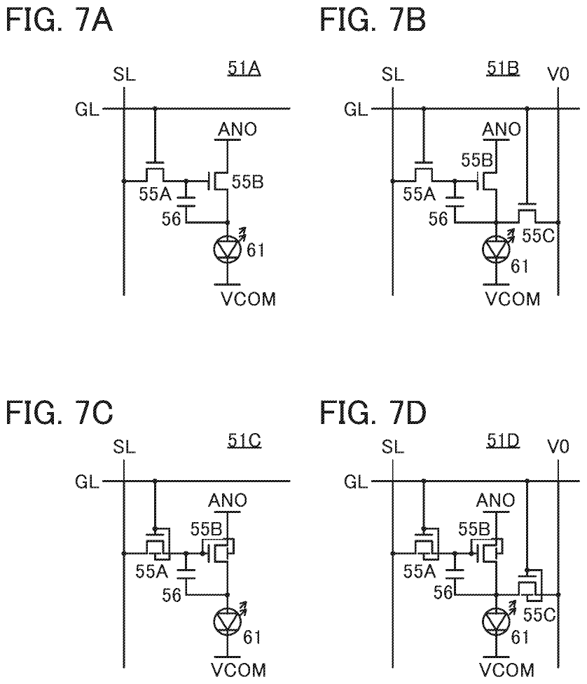

FIG. 7 to FIG. 9 illustrate structure examples of a pixel circuit usable as the pixel circuit 51 and the display element 61 connected to the pixel circuit 51. Note that in the following description, the display element 61 is a light-emitting device such as an organic EL element (OLED: Organic Light Emitting Diode).

Note that the light-emitting device described in one embodiment of the present invention is not limited to an organic EL element and can be a self-luminous light-emitting device such as an LED (Light Emitting Diode), a micro LED, a QLED (Quantum-dot Light Emitting Diode), or a semiconductor laser.

A pixel circuit 51A illustrated in FIG. 7A includes a transistor 55A, a transistor 55B, and a capacitor 56. FIG. 7A also illustrates the display element 61 connected to the pixel circuit 51A. FIG. 7A also illustrates the source line SL, the gate line GL, a power supply line ANO, and a power supply line VCOM.

A gate of the transistor 55A is electrically connected to the gate line GL, one of a source and a drain thereof is electrically connected to the source line SL, and the other thereof is electrically connected to a gate of the transistor 55B and one electrode of the capacitor 56. One of a source and a drain of the transistor 55B is electrically connected to the power supply line ANO and the other thereof is electrically connected to an anode of the display element 61. The other electrode of a capacitor C1 is electrically connected to the anode of the display element 61. A cathode of the display element 61 is electrically connected to the power supply line VCOM. Note that the anode and the cathode of the display element 61 can be interchanged with each other as appropriate by changing the level of potentials supplied to the power supply line ANO and the power supply line VCOM.

A pixel circuit 51B illustrated in FIG. 7B has a structure where a transistor 55C is added to the pixel circuit 51A. A gate of the transistor 55C is electrically connected to the gate line GL, one of a source and a drain thereof is electrically connected to the anode of the display element 61, and the other of the source and the drain thereof is electrically connected to a wiring VO.

A pixel circuit 51C illustrated in FIG. 7C is an example of the case where transistors having a pair of gates are used as the transistor 55A and the transistor 55B of the pixel circuit 51A. In addition, a pixel circuit 51D illustrated in FIG. 7D is an example of the case where such transistors are used in the pixel circuit 51B. Thus, current that can flow through the transistors can be increased. Note that although the transistors having a pair of gates are used as all the transistors here, one embodiment of the present invention is not limited thereto. A transistor including a pair of gates electrically connected to different wirings may be used. For example, when a transistor in which one of gates is electrically connected to a source is used, the reliability can be increased.

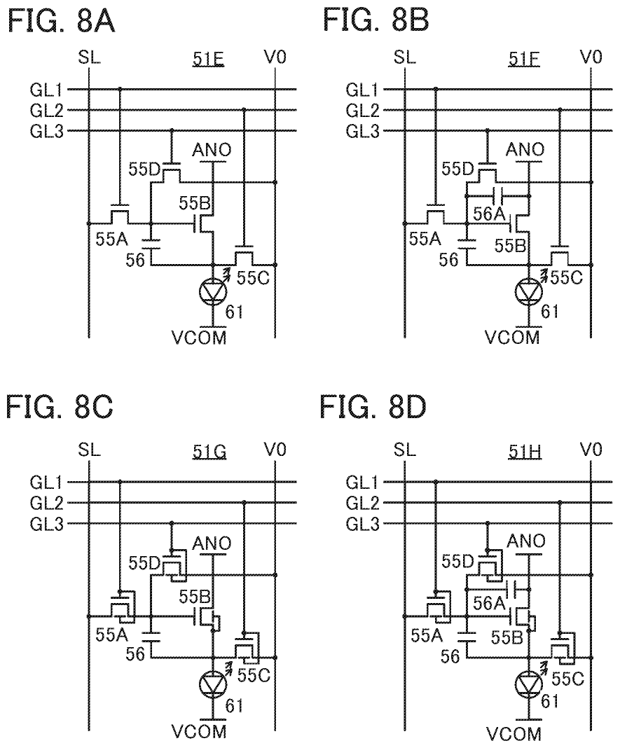

A pixel circuit 51E illustrated in FIG. 8A has a structure where a transistor 55D is added to the pixel circuit 51B. Three gate lines (a gate line GL1, a gate line GL2, and a gate line GL3) are electrically connected to the pixel circuit 51E.

A gate of the transistor 55D is electrically connected to the gate line GL3, one of a source and a drain of the transistor 55D is electrically connected to the gate of the transistor 55B, and the other of the source and the drain of the transistor 55D is electrically connected to the wiring VO. In addition, the gate of the transistor 55A is electrically connected to the gate line GL1, and the gate of the transistor 55C is electrically connected to the gate line GL2.

When the transistor 55C and the transistor 55D are brought into a conduction state at the same time, the source and the gate of the transistor 55B have the same potential, so that the transistor 55B can be brought into a non-conduction state in the case where the threshold voltage of the transistor 55B is higher than 0 V. Thus, current flowing through the display element 61 can be interrupted forcibly. Such a pixel circuit is suitable for the case of using a display method in which a display period and a non-lighting period are alternately provided.

A pixel circuit 51F illustrated in FIG. 8B is an example of the case where a capacitor 56A is added to the pixel circuit 51E. The capacitor 56A functions as a storage capacitor.

A pixel circuit 51G illustrated in FIG. 8C and a pixel circuit 51H illustrated in FIG. 8D are each an example of the case where a transistor including a pair of gates is used in the pixel circuit 51E or the pixel circuit 51F. A transistor whose pair of gates are electrically connected to each other is used as each of the transistor 55A, the transistor 55C, and the transistor 55D, and a transistor whose one of gates is electrically connected to a source is used as the transistor 55B.

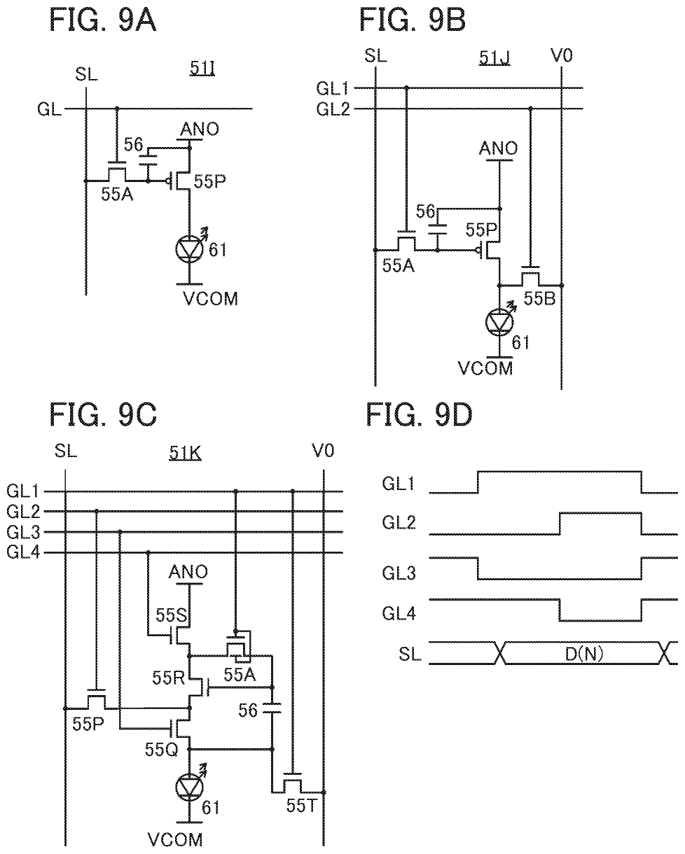

FIG. 7A to FIG. 8D each illustrate a structure example where the circuit can be formed using only OS transistors that are n-channel transistors; however, one embodiment of the present invention is not limited thereto. For example, as illustrated in FIG. 9A to FIG. 9C, a pixel circuit may have a structure including an OS transistor and an LTPS transistor.

A pixel circuit 51I illustrated in FIG. 9A includes the transistor 55A, a transistor 55P, and the capacitor 56. The pixel circuit 51I illustrated in FIG. 9A is an example of the case where the transistor 55B in the pixel circuit 51A is replaced with the transistor 55P, which is a p-channel LTPS transistor. In the pixel circuit 51I illustrated in FIG. 9A, an analog potential can be retained when the transistor 55A, which is an OS transistor, is brought into a non-conduction state. In the pixel circuit 51I, the amount of current flowing to the display element 61 can be increased when the transistor 55P, which is an LTPS transistor, is used as a driving transistor.

A pixel circuit 51J illustrated in FIG. 9B includes the transistor 55A, the transistor 55B, the transistor 55P, and the capacitor 56. The pixel circuit 51J illustrated in FIG. 9B is an example of the case where the transistor 55B in the pixel circuit 51B is replaced with the transistor 55P, which is a p-channel LTPS transistor. In the pixel circuit 51J illustrated in FIG. 9B, an analog potential can be retained when the transistor 55A, which is an OS transistor, is brought into a non-conduction state. In the pixel circuit 51J, the amount of current flowing to the display element 61 can be increased when the transistor 55P, which is an LTPS transistor, is used as a driving transistor.

A pixel circuit 51K illustrated in FIG. 9C includes the transistor 55A, the transistor 55P to a transistor 55T, and the capacitor 56. The pixel circuit 51K illustrated in FIG. 9C is an example of a pixel circuit including the transistor 55P to the transistor 55T, which are n-channel LTPS transistors. In the pixel circuit 51K illustrated in FIG. 9C, an analog potential can be retained when the transistor 55A, which is an OS transistor, is brought into a non-conduction state. In the pixel circuit 51K, the amount of current flowing to the display element 61 can be increased when the transistor 55P to the transistor T, which are LTPS transistors, are used as driving transistors or switching transistors.

FIG. 9D shows an operation timing chart of the pixel circuit 51K illustrated in FIG. 9C. When signals shown in FIG. 9D are supplied to the gate lines GL1 to GL4, light emission corresponding to image data D(N) of the source line SL can be controlled. Note that as shown in FIG. 9D, a selection signal and an inverted signal are supplied to the gate lines GL1 and GL3 and to the gate lines GL2 and GL4.

### <Structure Example of Gate Line Driver Circuit>

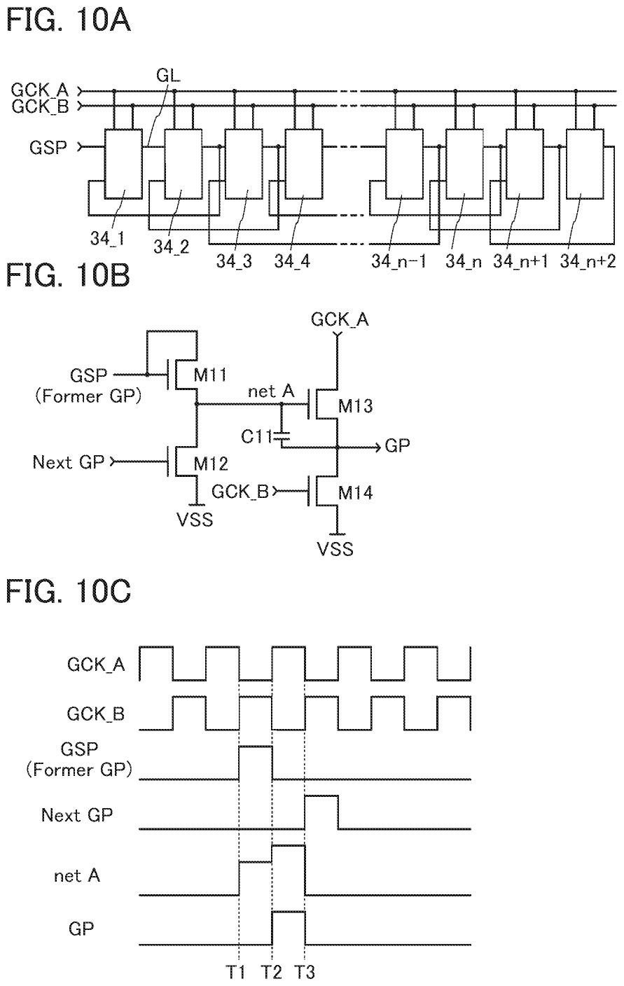

FIG. 10A to FIG. 10C show examples of the gate line driver circuit 33 described with reference to FIG. 2B, FIG. 6, and the like, the pulse output circuit 34 that can be used in the gate line driver circuit 33, and a timing chart.

FIG. 10A illustrates an example of a shift register included in the gate line driver circuit 33. FIG. 10A illustrates pulse output circuits 34_1 to 34_n+2, a wiring for supplying a gate clock signal GCK_A, a wiring for supplying a gate clock signal GCK_B, and a wiring for supplying a gate start pulse GSP. Note that a wiring between the pulse output circuits 34_1 and 34_2 is connected to the gate line GL. Output signals from the pulse output circuits 34_n+1 and 34_m+2 are each a signal for resetting the pulse output circuit in the previous stage.

FIG. 10B illustrates a circuit structure example of a pulse output circuit that can be used as each of the pulse output circuits 34_1 to 34_n+2 illustrated in FIG. 10A. The pulse output circuit 34 illustrated in FIG. 10B includes transistors M11 to M14 and a capacitor C11. As signals and a voltage to be supplied to the transistors, FIG. 10B shows the gate clock signal GCK_A, the gate clock signal GCK_B, an output signal GP, the gate start pulse GSP (or an output signal of the previous pulse output circuit 34 “Former GP”), an output signal of the next pulse output circuit 34 “Next GP”, and a voltage VSS. FIG. 10B also illustrates a node connected to the transistors M11, M12, and M13 and the capacitor C11, which is indicated by net A.

FIG. 10C is a timing chart for describing the operation of the pulse output circuit illustrated in FIG. 10B. At time T1 in FIG. 10C, GCK_A is at a low level and GCK_B is at a high level, and GSP is set at the high level at this time so as to increase the voltage of net A. At time T2, GSP is at the low level, so that “net A” is brought into a floating state. Since GCK_A is at the high level and GCK_B is at the low level at the time T2, the voltage of net A in a floating state increases owing to capacitive coupling of the capacitor C11. Thus, the transistor M13 is brought into a conduction state and GP becomes at the high level. At time T3, Next GL becomes at the high level, whereby net A becomes at the low level, and GCK_B becomes at the high level, whereby GP becomes at the low level.

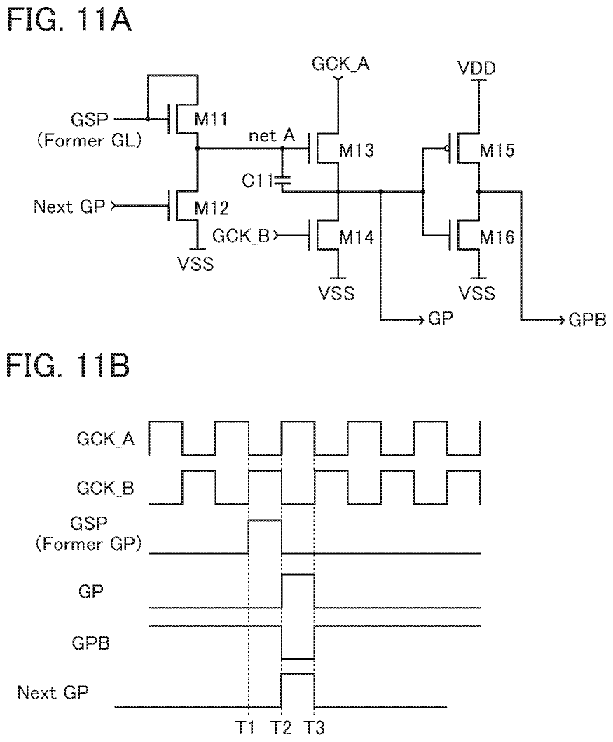

In the case where the above-described pixel circuit 51K and the like illustrated in FIG. 9C are driven, an inverted signal of the output signal GP in FIG. 10C is needed. An inverted signal of the output signal GP is preferably generated in an inverter circuit formed of a CMOS circuit. That is, as illustrated in FIG. 11A, in the structure of the pulse output circuit described with reference to FIG. 10B, it is preferable to provide a p-channel transistor M15 and an n-channel transistor M16 included in an inverter circuit that generates an inverted signal of the output signal GP. The transistor M15 can be an LTPS transistor, and the transistor M16 can be an LTPS transistor or an OS transistor.

FIG. 11B is a timing chart for describing the operation of the pulse output circuit illustrated in FIG. 11A. As illustrated in FIG. 11B, it is possible to generate a signal that makes GPB, which is an inverted signal, turn to a low level at a timing when GP turns to a high level.

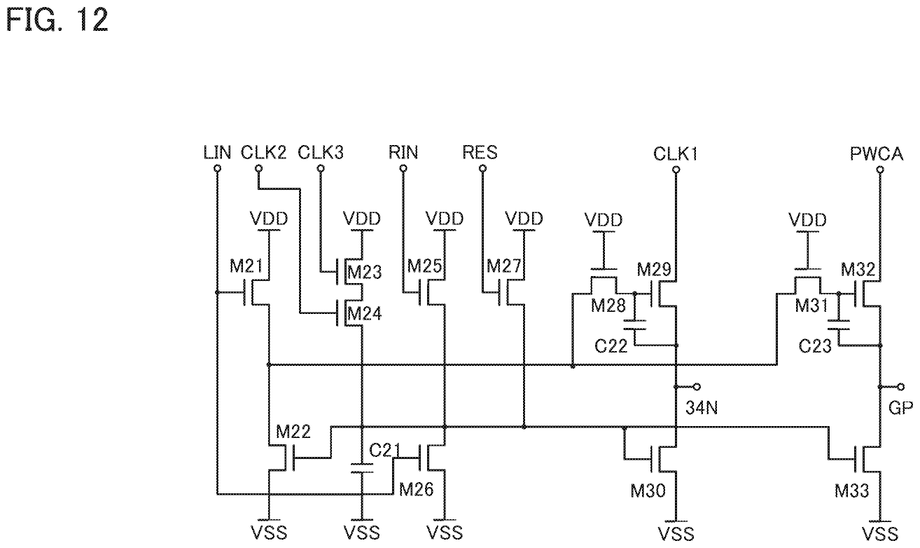

Note that the pulse output circuit is not limited to having the circuit structures illustrated in FIG. 10B and FIG. 11A and may have another structure. FIG. 12 illustrates transistors M21 to M33 and capacitors C21 to C23. Note that in FIG. 12, LIN is an output signal of the previous stage or a gate start pulse, CLK1 to CLK3 are gate clock signals, RES is a reset signal, RIN is an output signal of the subsequent stage, and PWCA is a pulse width control signal. Note that the output signal GP is a signal output to the gate line GL, and an output signal 34N is a signal output to the pulse output circuit in the subsequent stage.

As illustrated in FIG. 12, the pulse output circuit can have a circuit structure that can be formed using only n-channel transistors. In FIG. 12, the transistors M21 to M33 are n-channel transistors, and a circuit structure formed of an OS transistor or an n-channel LTPS transistor or a circuit structure combining an OS transistor and an n-channel LTPS transistor can be employed.

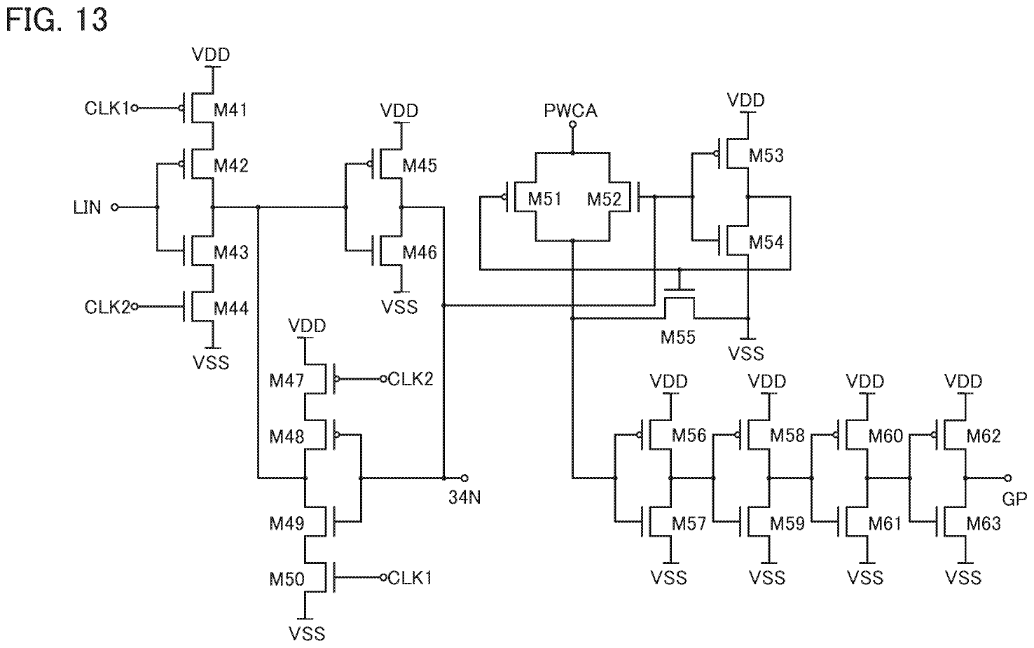

Note that the pulse output circuit is not limited to having the circuit structure illustrated in FIG. 10B, FIG. 11A, and FIG. 12 and may have another structure. FIG. 13 illustrates transistors M41 to M63. Note that in FIG. 13, LIN is an output signal of the previous stage or a gate start pulse, CLK1 and CLK2 are gate clock signals, and PWCA is a pulse width control signal. Note that the output signal GP is a signal output to the gate line GL, and the output signal 34N is a signal output to the pulse output circuit in the subsequent stage.

As illustrated in FIG. 13, the pulse output circuit can have a circuit structure formed with a combination of an n-channel transistor and a p-channel transistor. With an n-channel transistor and a p-channel transistor, a circuit structure including an n-channel OS transistor and a p-channel LTPS transistor or a circuit structure including a p-channel LTPS transistor and an n-channel LTPS transistor can be formed.

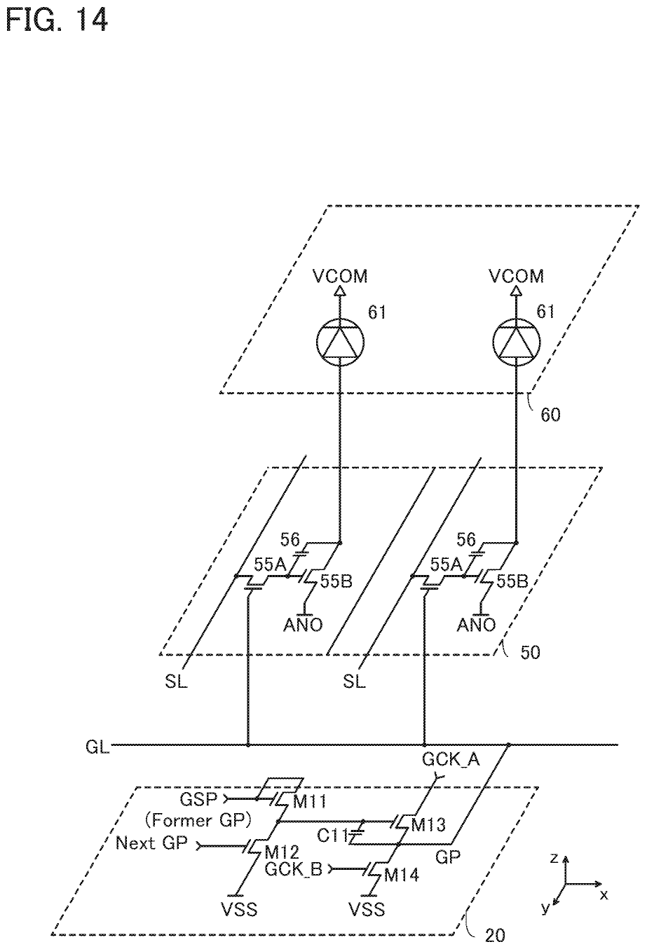

FIG. 14 illustrates, with use of circuit symbols, a structure example where the pixel circuits 51A in FIG. 7A and the pulse output circuit in FIG. 10B are stacked. Note that in FIG. 14, the x direction, the y direction, and the z direction are shown as in FIG. 6. FIG. 14 illustrates the pulse output circuit, the pixel circuits, and the light-emitting elements as the display elements, which respectively correspond to the layer 20, the layer 50, and the layer 60 described with reference to FIG. 1B.

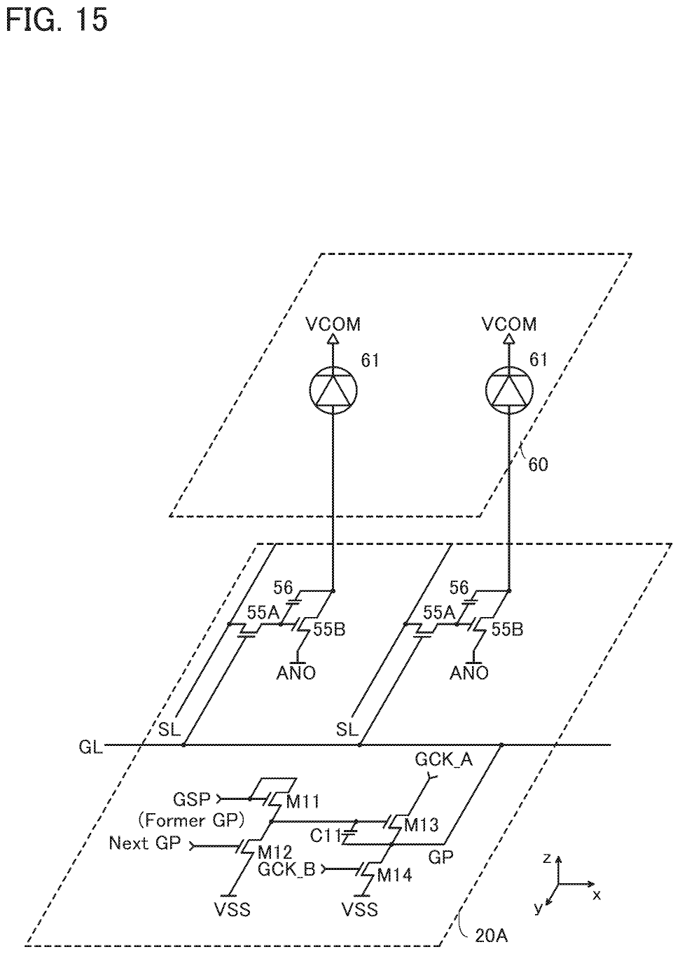

Note that in the case where the pixel circuit and the gate line driver circuit are provided in the same layer as described with reference to FIG. 3A and FIG. 3B in the structure of FIG. 14, the structure becomes like a structure example illustrated in FIG. 15. FIG. 15 illustrates, with use of circuit symbols, a structure example where the pixel circuit 51A in FIG. 7A and the pulse output circuit in FIG. 10B are placed in the layer 20A. Note that in FIG. 15, the x direction, the y direction, and the z direction are shown as in FIG. 14. FIG. 15 illustrates the pulse output circuit, the pixel circuits, and the light-emitting elements as the display elements, which correspond to the layer 20A and the layer 60 described with reference to FIG. 3A and FIG. 3B.

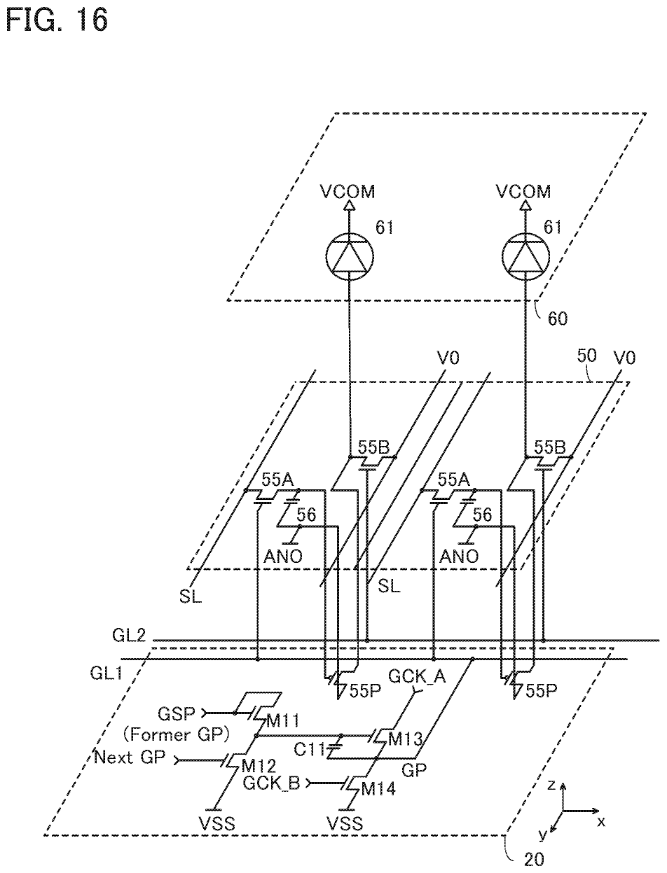

FIG. 16 illustrates, with use of circuit symbols, a structure example where the pixel circuits 51J in FIG. 9B and the pulse output circuit in FIG. 10B are stacked. Note that in FIG. 16, the x direction, the y direction, and the z direction are shown as in FIG. 6. Like FIG. 14 and FIG. 15, FIG. 16 illustrates the pulse output circuit, the pixel circuits, and the light-emitting elements as the display elements, which respectively correspond to the layer 20, the layer 50, and the layer 60 described with reference to FIG. 1B.

The diagram illustrated in FIG. 16 is different from FIG. 14 in that the transistor 55P included in the pixel circuit is provided in the layer 20. In the structure of one embodiment of the present invention, a circuit other than the pulse output circuit, e.g., part of the pixel circuit, can be provided in the layer 20. Since the number of transistors in the layer 50 can be reduced, the area of the pixel circuit can be reduced and a display apparatus with a higher resolution can be obtained.

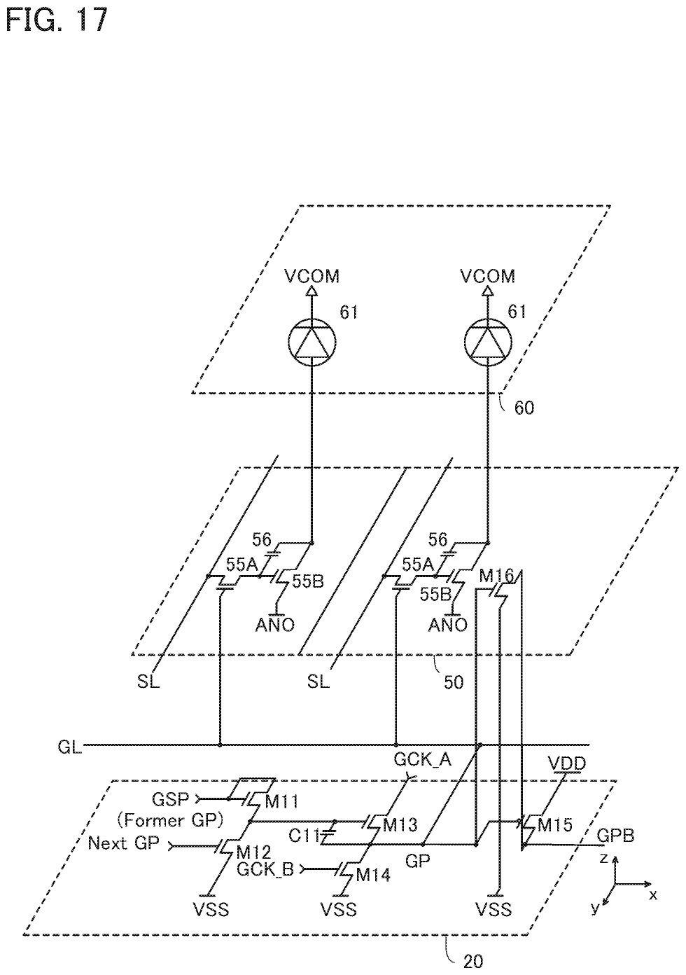

FIG. 17 illustrates, with use of circuit symbols, a structure example where the pixel circuits 51A in FIG. 7A and the pulse output circuit in FIG. 11A are stacked. Note that in FIG. 17, the x direction, the y direction, and the z direction are shown as in FIG. 14 to FIG. 16. Like FIG. 14 to FIG. 16, FIG. 17 illustrates the pulse output circuit, the pixel circuits, and the light-emitting elements as the display elements, which respectively correspond to the layer 20, the layer 50, and the layer 60 described with reference to FIG. 1B.

The diagram illustrated in FIG. 17 is different from FIG. 14 to FIG. 16 in that the transistor M16 included in the pulse output circuit is provided in the layer 50. In the structure of one embodiment of the present invention, a circuit other than the pixel circuit, e.g., part of the pulse output circuit, can be provided in the layer 50. Since the number of transistors in the layer 20 can be reduced, the area of the pulse output circuit can be reduced.

As described above, in one embodiment of the present invention, the pixel circuit and the pulse output circuit included in the gate line driver circuit can have not only a circuit structure including only OS transistors or only LTPS transistors but also a circuit structure combining an OS transistor and an LTPS transistor. Accordingly, in one embodiment of the present invention, the layout flexibility of the pixel circuit and the pulse output circuit included in the gate line driver circuit can be increased, so that the shape flexibility of the display portion can be increased and a well-designed display apparatus can be obtained.

### <Operation Example of Display Apparatus>

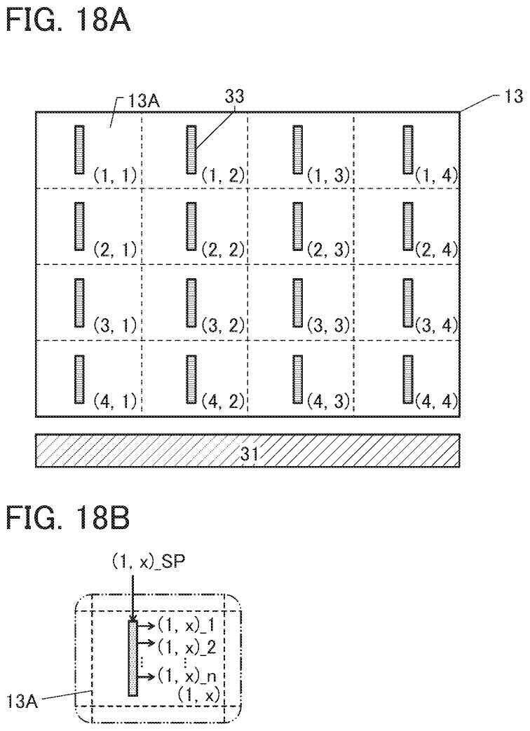

FIG. 18A is a schematic view illustrating a display apparatus in which the sections of the pixel circuit portion 57 and the sections 39 of the driver circuit portion 30 described with reference to FIG. 2A and FIG. 2B are arranged in 4 rows and 4 columns, that is, m=4 and n=4, and the display portion 13 in FIG. 1A is divided into 16 sub-display portions 13A. Note that in FIG. 18A, the 16 divided sub-display portions 13A are denoted by reference numerals such as (1,1) to (4,4). In FIG. 18A, the gate line driver circuit 33 is provided in each of the sub-display portions 13A, and the source line driver circuit 31 is provided outside the display portion 13.

FIG. 18B is a schematic view for describing signals output to gate lines from the gate line driver circuit 33 corresponding to the sub-display portion 13A illustrated in FIG. 18A. Note that (1,x) shown in FIG. 18B denotes any one of the sub-display portions 13A of (1,1) to (1,4), which are the sub-display portions 13A in the first row. That is, (2,1) to (2,4), which are the sub-display portions 13A in the second row, can be denoted by (2,x). Similarly, (3,1) to (3,4), which are the sub-display portions 13A in the third row, can be denoted by (3,x), and (4,1) to (4,4), which are the sub-display portions 13A in the fourth row, can be denoted by (4,x).

In addition, (1,x) _SP shown in FIG. 18B denotes a start pulse signal supplied to each of the gate line driver circuits 33 of (1,1) to (1,4), which are the sub-display portions 13A in the first row. In addition, (1,x) _1 to (1,x) _n (n is a natural number) denote output signals that are sequentially output from the pulse output circuits of the gate line driver circuits 33 of (1,1) to (1,4), which are the sub-display portions 13A in the first row.

In the structure of FIG. 18A where screen scanning is performed in one determined direction, partial rewriting can be performed by operating the gate driver only in a block to be rewritten.

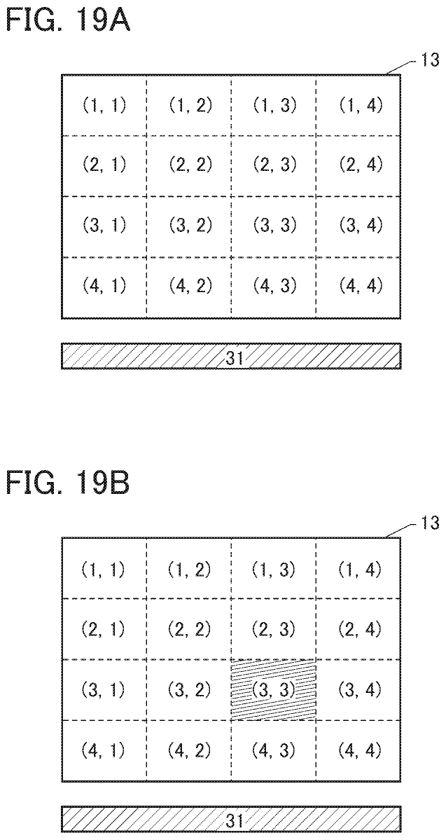

Next, methods for operating the gate line driver circuit in image data rewriting are described with reference to timing charts. Here, a timing chart of image data rewriting in all of the sub-display portions 13A of the display portion 13 (a schematic view shown in FIG. 19A) and a timing chart of image data rewriting only in the sub-display portion 13A in the third row and the third column of the display portion 13 (a shadowed portion denoted by (3,3) in the figure) (a schematic view illustrated in FIG. 19B) are described.

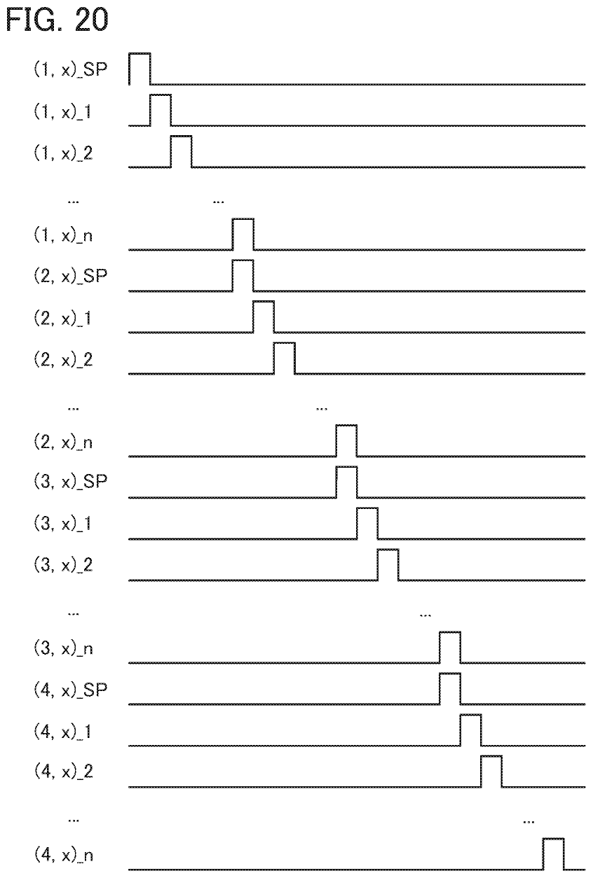

FIG. 20 shows, in addition to the start pulse signals (1,x) _SP to (4,x) _SP supplied to the gate line driver circuits of the respective rows in image data rewriting corresponding to the schematic view shown in FIG. 19A, the output signals (1,x) _1 to (1,x) _n, (2,x) _1 to (2,x) _n, (3,x) _1 to (3,x) _n, and (4,x) _1 to (4,x) _n from the gate line driver circuits of the respective rows.

As shown in FIG. 20, in image data rewriting corresponding to the schematic view shown in FIG. 19A, the start pulse signal (1,x) is input to each of the gate line driver circuits of the sub-display portions of (1,1), (1,2), (1,3), and (1,4) so that output signals are sequentially output from the gate line driver circuits. Next, the start pulse signal (2,x) is input to each of the gate line driver circuits of the sub-display portions of (2,1), (2,2), (2,3), and (2,4) so that output signals are sequentially output from the gate line driver circuits. Next, the start pulse signal (3,x) is input to each of the gate line driver circuits of the sub-display portions of (3,1), (3,2), (3,3), and (3,4) so that output signals are sequentially output from the gate line driver circuits. Next, the start pulse signal (4,x) is input to each of the gate line driver circuits of the sub-display portions of (4,1), (4,2), (4,3), and (4,4) so that output signals are sequentially output from the gate line driver circuits.

By the operation shown in FIG. 20, output signals can be generated in the gate line driver circuits so that image data output from the source line driver circuit is selected row by row and written to each pixel.

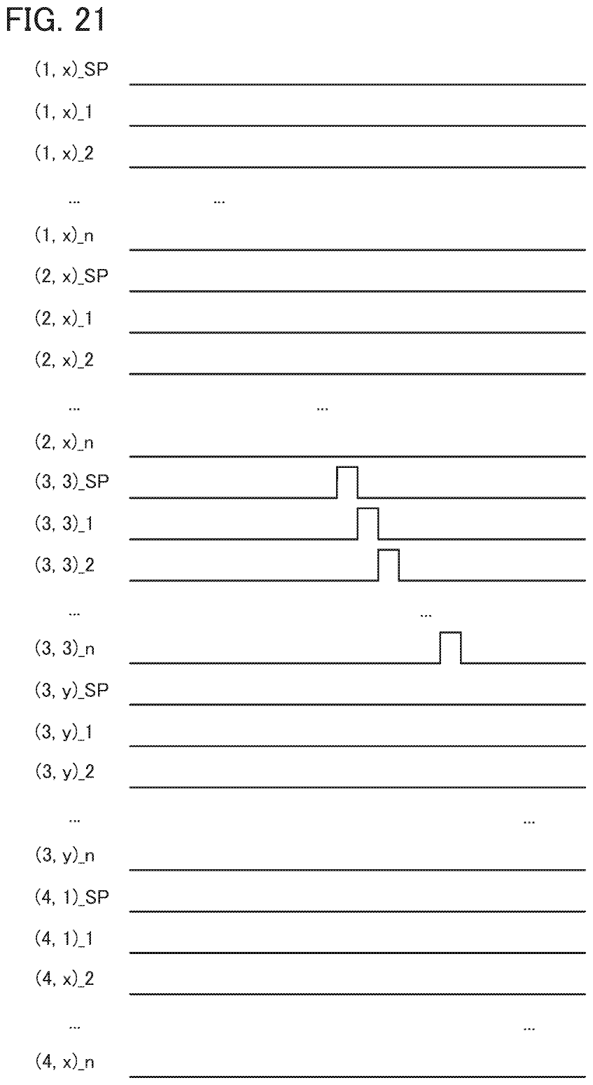

FIG. 21 shows, in addition to the start pulse signals (1,x) _SP to (4,x) _SP supplied to the gate line driver circuits of the respective rows in image data rewriting corresponding to the schematic view shown in FIG. 19B, the output signals (1,x) _1 to (1,x) _n, (2,x) _1 to (2,x) _n, (3,x) _1 to (3,x) _n, and (4,x) _1 to (4,x) _n from the gate line driver circuits of the respective rows.

As shown in FIG. 21, in image data rewriting corresponding to the schematic view shown in FIG. 19B, the start pulse signal (3,3) _SP is input to the gate line driver circuit of the sub-display portion of (3,3) so that output signals are sequentially output from the gate line driver circuit of the sub-display portion (3,3). No start pulse signal is output to the gate line driver circuits of the other sub-display portions so that output signals are not output sequentially from the corresponding gate line driver circuits.

By the operation shown in FIG. 21, the operation of the gate line driver circuit of the display portion where rewriting is not performed can be stopped; thus, power consumption can be reduced.

Although the structure is shown where the gate line driver circuit is placed in each of the sub-display portions as illustrated in FIG. 18A, the gate line driver circuit may be shared by adjacent sub-display portions.

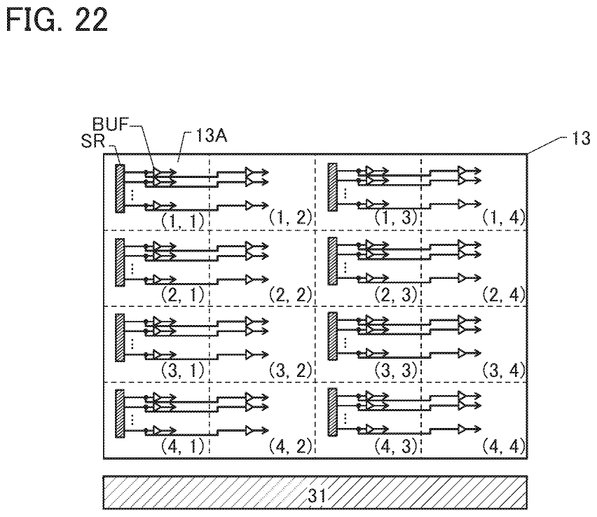

For example, in the structure where the display portion is divided into 4×4 blocks as illustrated in FIG. 18A, a shift register of the gate line driver circuit may be shared by the sub-display portion in the first column and the sub-display portion in the second column, and a shift register of the gate driver may be shared by the sub-display portion in the third column and the sub-display portion in the fourth column. FIG. 22 is a schematic view of this case.

As illustrated in FIG. 22, although a shift register SR of the gate line driver circuit is shared by a plurality of sub-display portions, a buffer BUF (a portion supplied with a selection signal for a pixel) is separately provided for each sub-display portion. For example, when image data rewriting is performed only in the sub-display portion 13A of (1,2), a signal supplied to the buffer BUF of the sub-display portion 13A of (1,1) is stopped, whereby rewriting can be performed only in the sub-display portion of (1,2).

### <Structure Example of Source Line Driver Circuit>

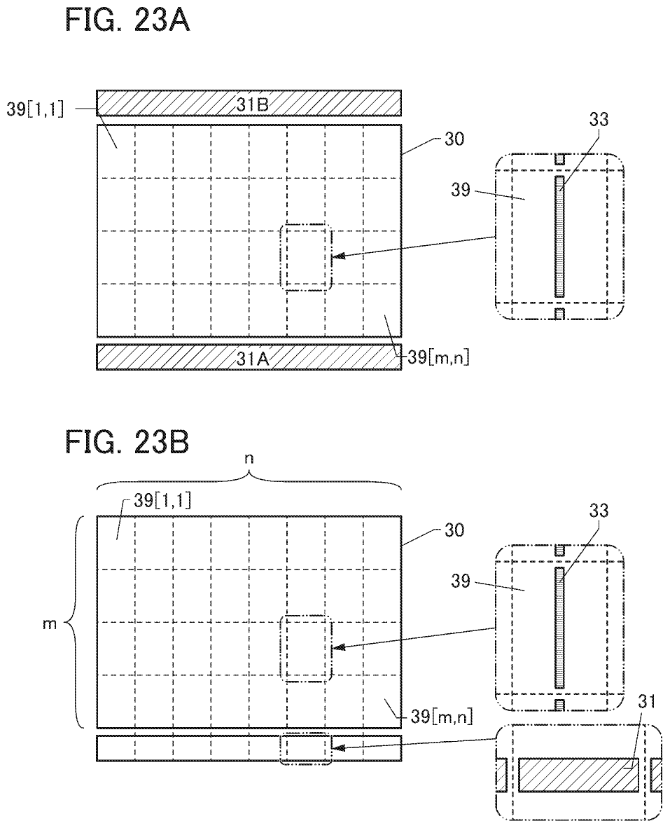

FIG. 23A and FIG. 23B illustrate variation examples of the source line driver circuit 31 described with reference to FIG. 2B and the like.

FIG. 23A illustrates a structure example where a plurality of source line driver circuits 31 described with reference to FIG. 2B and the like are provided. FIG. 23A illustrates a structure where a source line driver circuit 31A and a source line driver circuit 31B are provided in regions corresponding to the upper side and the lower side of the driver circuit portion 30 that includes the plurality of sections 39 provided with the gate line driver circuits 33. This structure enables the source line driver circuit 31A and the source line driver circuit 31B to supply image data to different divided sections in the pixel circuit portion, whereby the operation of the source line driver circuit can be paused in accordance with the operation of the corresponding gate line driver circuits that do not output the output signals sequentially.

Although FIG. 23A illustrates a structure where two source line driver circuits are provided, the source line driver circuit is preferably provided to be divided in accordance with the number of sub-display portions. For example, as illustrated in FIG. 23B, the number of source line driver circuits 31 is preferably the same as that of columns of the sections 39 corresponding to the sub-display portions, that is, the same as n. With this structure, the gate line driver circuit corresponding to the operating sub-display portion and the source line driver circuit corresponding to the column of the operating sub-display portion can be operated and the operations of the other gate line driver circuits and the other source line driver circuits can be paused, leading to a reduction in power consumption of the display apparatus.

### <Structure Example 2 of Display Apparatus>

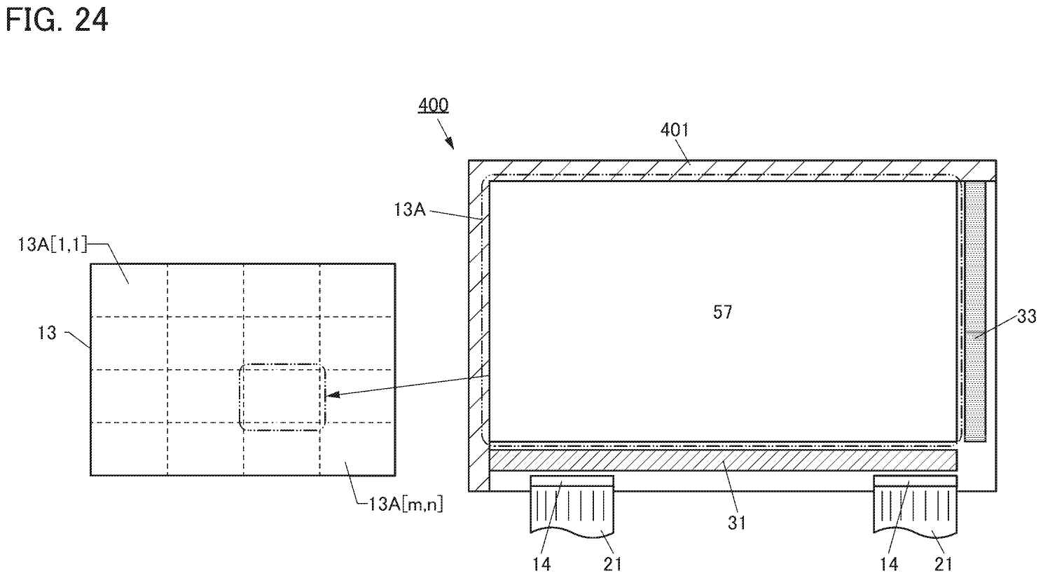

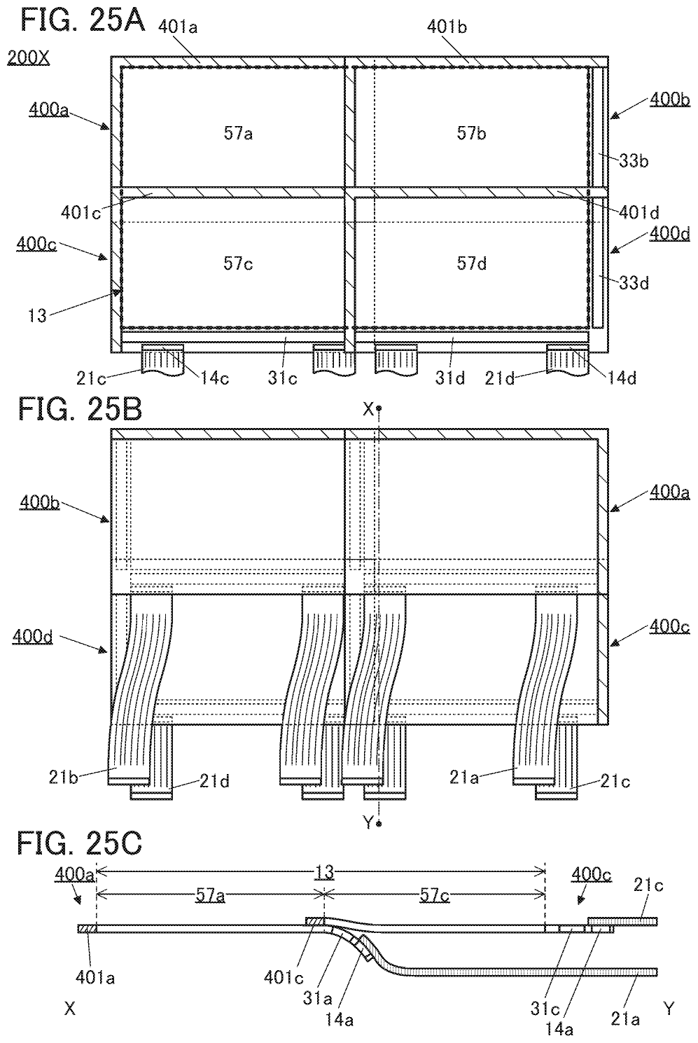

FIG. 24 to FIG. 25 illustrate a structure example of a display apparatus in which a plurality of display panels are combined.

FIG. 24 illustrates an example of the case where the display portion 13 of the display apparatus is formed with a combination of display panels 400 described below as examples. FIG. 25 is a schematic top view of the display portion 13 and the display panels 400 seen from the display surface side.

The display panel 400 includes the sub-display portion 13A, the pixel circuit portion 57, the source line driver circuit 31, the gate line driver circuit 33, a region 401 transmitting visible light, the terminal portion 14, and the like. FIG. 24 illustrates an example where the display panel 400 includes two terminal portions 14 and an FPC 21 is connected to each of the terminal portions 14.

Although the gate line driver circuit 33 is provided at the periphery of the pixel circuit portion 57 in FIG. 24, the structure is not limited to this. For example, as described with reference to FIG. 1A to FIG. 2B, a structure can be employed where transistors are provided in a plurality of layers and the gate line driver circuits and the pixel circuit portion are placed to overlap with each other. As another structure, as described with reference to FIG. 3A and FIG. 3B, a structure may be employed where the gate line driver circuit is placed in a region provided with the pixel circuit portion in a layer including transistors.

In the case of the sub-display portions 13A in m rows and n columns, a sub-display portion 13A[1,1] to a sub-display portion 13A[m,n] are provided in the display portion 13. That is, combining the display panels 400 can form a display apparatus including the plurality of sub-display portions 13A.

The region 401 is a region transmitting visible light. For a member provided in the region 401, a material transmitting visible light can be used. Alternatively, a light-blocking material processed to be narrow enough to be invisible (with a width of less than or equal to 5 μm, for example) can be used.

FIG. 25A and FIG. 25B illustrate a structure example of a display apparatus 200X including four display panels (a display panel 400a, a display panel 400b, a display panel 400c, and a display panel 400d). FIG. 25A is a schematic top view of the display apparatus 200X seen from the display surface side, and FIG. 25B is a schematic top view of the display apparatus seen from the opposite side of the display surface (also referred to as a rear surface side).

Note that in the following description, unless otherwise specified, the display panels or components of the display panels are denoted by reference signs a to d to be distinguished from each other. In the case where matters common to the display panels, the components of the display panels, and the like are described, these reference signs are not used in some cases.

In FIG. 25A and FIG. 25B, the display panel 400a, the display panel 400b, the display panel 400c, and the display panel 400d are stacked in this order from the rear surface side. The display panel 400a is positioned on the rear surface side, and the display panel 400d is positioned closest to the display surface.

Here, part of a region 401b included in the display panel 400b is provided to overlap with part of a pixel circuit portion 57a in a region overlapping with the display element. In the part of the pixel circuit portion 57a overlapping with the region 401b, light from the display element is emitted to the display surface side passing through the region 401b.

Similarly, part of a region 401c included in the display panel 400c is provided to overlap with part of the pixel circuit portion 57a. Part of a region 401d included in the display panel 400d is provided to overlap with part of the pixel circuit portion 57a, another part of the region 401d is provided to overlap with part of a pixel circuit portion 57b, and another part of the region 401d is provided to overlap with part of a pixel circuit portion 57c.

That is, the display portion 13 of the display apparatus 200X includes the pixel circuit portion 57a, the pixel circuit portion 57b, the pixel circuit portion 57c, and a pixel circuit portion 57d. Thus, a display apparatus in which the pixel circuit portion 57a, the pixel circuit portion 57b, the pixel circuit portion 57c, and the pixel circuit portion 57d of the display panels 400a to 400d correspond to the sub-display portions can be achieved.

As illustrated in FIG. 25B, an FPC 21a connected to the display panel 400a and an FPC 21b connected to the display panel 400b are provided to overlap with the display panel 400c and the display panel 400d, respectively.

Here, the display panels 400 are each provided with the source line driver circuit 31 and the gate line driver circuit 33; thus, the number of signals supplied to each display panel 400 can be reduced. This can reduce the number of FPCs 21 connected to one display panel 400, thereby reducing the number of components. As illustrated in FIG. 25B, the lengths of the FPCs 21 connected to the display panels 400 are made different, and the end portions of the FPCs 21 are collected to one side of the display apparatus 200X; accordingly, the driver circuits for supplying a signal or the like to the display apparatus 200X can be gathered in one place. Thus, the structure on the rear side of the display apparatus 200X can be simplified.

FIG. 25C is a schematic cross-sectional view of the display apparatus 200X cut along the dashed-dotted line X-Y in FIG. 25B.

A portion of the display panel 400a overlapping with the display panel 400c is curved in the rear surface direction, and the FPC 21a is connected to the terminal portion 14a in the portion. In this case, the source line driver circuit 31A and the terminal portion 14A of the display panel 400a are placed to overlap with the pixel circuit portion 57c of the display panel 400c. Thus, the display portion 13 of the display apparatus 200X can display a seamless image with high display quality.

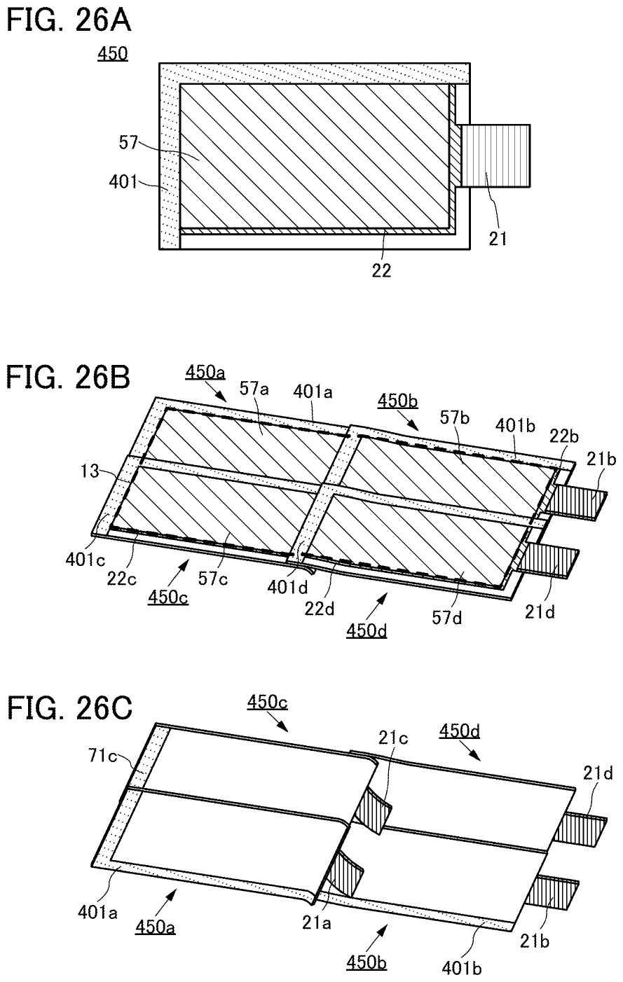

Another structure example of a display apparatus in which a plurality of display panels are combined is described with reference to FIG. 26A to FIG. 26C. A display panel 450 illustrated in FIG. 26A includes the pixel circuit portion 57, the region 401, and a region 22. The region 22 is a region blocking visible light. The region 401 and the region 22 are each provided to be adjacent to the pixel circuit portion 57. FIG. 26A illustrates an example where the display panel 450 is provided with the FPC 21. Note that the gate line driver circuit and the source line driver circuit are not provided in the display panel, and image data and other signals are input from the outside through the FPC.

Although FIG. 26A to FIG. 26C illustrate a structure where the gate line driver circuit and the source line driver circuit are provided outside the display panel, the structure is not limited thereto. For example, the source line driver circuit may be provided outside the display panel, and the gate line driver circuit may be provided in a region overlapping with the pixel circuit. In this case, as described with reference to FIG. 1A to FIG. 2B, a structure can be employed where transistors are provided in a plurality of layers and the gate line driver circuits are provided to overlap with the pixel circuit portion. As another structure, as described with reference to FIG. 3A and FIG. 3B, a structure may be employed where the gate line driver circuit is placed in a region provided with the pixel circuit portion in a layer including transistors.

The pixel circuit portion 57 includes a plurality of pixel circuits. In the region 401, a pair of substrates included in the display panel 450 and a sealant for sealing the display element interposed between the pair of substrates may be provided, for example. In that case, a material having a property of transmitting visible light is used for a member provided in the region 401. The region 22 is provided with a wiring electrically connected to the pixel included in the pixel circuit portion 57, for example. Furthermore, a terminal connected to the FPC 21, a wiring connected to the terminal, or the like may be provided in the region 22.

FIG. 26B and FIG. 26C illustrate an example where the display panels 450 illustrated in FIG. 26A are arranged as 2×2 sub-display portions in a matrix (two display panels 450 are arranged in each of the longitudinal direction and the lateral direction). FIG. 26B is a perspective view of the display surface side of the display panel 450 and FIG. 26C is a perspective view of the side opposite to the display surface of the display panel 450.

The four display panels 450 (the display panels 450a, 450b, 450c, and 450d) are arranged to include overlapping regions. Specifically, the display panels 450a, 450b, 450c, and 450d are arranged such that the region 401 included in one display panel 450 includes a region overlapping with the upper side (display surface side) of the pixel circuit portion 57 included in another display panel 450. The display panels 450a, 450b, 450c, and 450d are arranged such that the region 22 blocking visible light included in one display panel 450 does not overlap with the upper sides of the pixel circuit portions 57 of the other display panels 450. In a portion where the four display panels 450 overlap with one another, the display panel 450b overlaps with the display panel 450a, the display panel 450c overlaps with the display panel 450b, and the display panel 450d overlaps with the display panel 450c.

The short sides of the display panels 450a and 450b overlap with each other, and part of the pixel circuit portion 57a and part of the region 401b overlap with each other. The long sides of the display panels 450a and 450c overlap with each other, and part of the pixel circuit portion 57a and part of the region 401c overlap with each other.

Part of the pixel circuit portion 57b overlaps with part of the region 401d. Part of the pixel circuit portion 57c overlaps with part of the region 401d.

Thus, regions where the pixel circuit portions 57a to 57d are placed with substantially no seam can be the sub-display portions of the display portion 13 of the display apparatus.

Here, the display panel 450 preferably has flexibility. For example, a pair of substrates included in the display panel 450 preferably has flexibility.

Thus, as illustrated in FIG. 26B and FIG. 26C, the vicinity of the FPC 21a of the display panel 450a can be bent and part of the display panel 450a and part of the FPC 21a can be placed under the pixel circuit portion 57b of the display panel 450b adjacent to the FPC 21a. As a result, the FPC 21a can be placed without physical interference with the rear surface of the display panel 450b. Furthermore, when the display panel 450a and the display panel 450b are fixed to overlap with each other, it is not necessary to consider the thickness of the FPC 21a; thus, a difference in the height between the top surface of the region 401b transmitting visible light and the top surface of the display panel 450a can be reduced. This can make an end portion of the display panel 450b positioned over the pixel circuit portion 57a less noticeable.

Moreover, when each display panel 450 has flexibility, the display panel 450b can be bent gently so that the top surface of the pixel circuit portion 57b of the display panel 450b and the top surface of the pixel circuit portion 57a of the display panel 450a are level with each other. Thus, the display regions can have uniform height except in the vicinity of a region where the display panel 450a and the display panel 450b overlap with each other, and the display quality of a video displayed on a display region 79 can be improved.

Although the relationship between the display panel 450a and the display panel 450b is taken as an example in the above description, the same applies to the relationship between other two adjacent display panels 450.

Note that to reduce the step between two adjacent display panels 450, the thicknesses of the display panels 450 are preferably small. For example, the thickness of the display panel 450 is preferably less than or equal to 1 mm, further preferably less than or equal to 300 μm, still further preferably less than or equal to 100 μm.

Although the above structure example of a display apparatus shows a structure where the FPC 21 is provided for the terminal portion 14 provided on a side where the display portion 13 is seen (the display surface side), the structure is not limited thereto. For example, the terminal portion 14 electrically connected to the FPC 21 can be exposed on the rear side of the side where the display portion 13 is seen (the rear surface side).

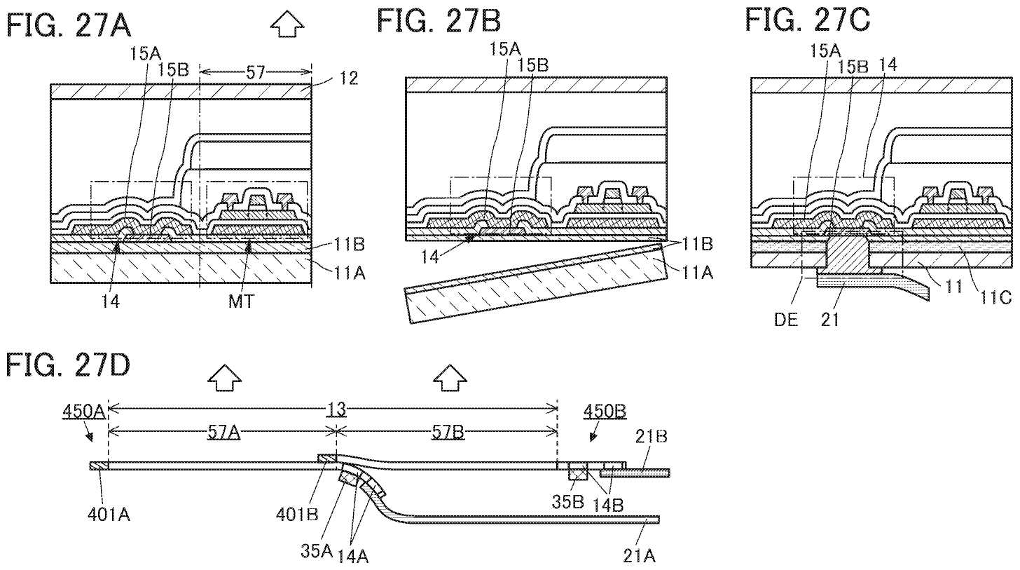

FIG. 27A to FIG. 27C are diagrams illustrating a structure where the terminal portion 14 is exposed on the rear surface side and the terminal portion 14 and the FPC 21 are connected to each other through an electrode penetrating the substrate 11 (a through electrode). For easy description, FIG. 27A to FIG. 27C illustrate a transistor MT provided in the pixel circuit portion 57 and the terminal portion 14 including conductive layers 15A and 15B as components of the display panel 450.

FIG. 27A is a schematic cross-sectional view of a display panel before the conductive layers 15A and 15B are exposed in the terminal portion 14. The transistor MT and the terminal portion 14 are provided between a substrate 11A and the substrate 12. A peeling layer 11B is provided between the substrate 11A and each of the transistor MT and the terminal portion 14.

As the substrate 11A, a glass substrate, a quartz substrate, a sapphire substrate, a ceramics substrate, a metal substrate, a semiconductor substrate, or the like can be used. Alternatively, a plastic substrate having heat resistance to the processing temperature in this embodiment may be used. The peeling layer 11B can be formed using an element selected from tungsten, molybdenum, titanium, tantalum, niobium, nickel, cobalt, zirconium, ruthenium, rhodium, palladium, osmium, iridium, and silicon, an alloy material containing the element, or a compound material containing the element. The peeling layer 11B can be formed to have a single-layer structure or a stacked-layer structure using any of these materials.

FIG. 27B is a schematic cross-sectional view of a display panel in which the substrate 11A is peeled at the peeling layer 11B to expose the conductive layer 15A and the conductive layer 15B in the terminal portion 14. Examples of a method for peeling the substrate 11A at the peeling layer 11B include application of mechanical force (e.g., processing of peeling with a human hand or a jig, processing of separation while a roller is rotated, or processing with ultrasonic waves).

FIG. 27C is a schematic cross-sectional view of a display panel in which the substrate 11 is attached to the conductive layers 15A and 15B exposed in the terminal portion 14 with an adhesive layer 11C and a through electrode DE and the FPC 21 are provided. Note that an opening portion of the substrate 11 provided with the through electrode DE is preferably provided by processing the substrate 11 before the substrate 11 is attached.

As the adhesive layer 11C, a photocurable adhesive, a reactive curable adhesive, a thermosetting adhesive, or an anaerobic adhesive can be used. Alternatively, an adhesive sheet or the like may be used. For the substrate 11 attached to the above-described display panel, it is possible to use an organic resin material, a glass material that is thin enough to have flexibility, a metal material (including an alloy material) that is thin enough to have flexibility, or the like.

The through electrode DE can be formed using any of a variety of anisotropic conductive films (ACFs), anisotropic conductive paste (ACP), or the like. The through electrode DE is formed by curing a paste-form or sheet-form material that is obtained by mixing conductive particles to a thermosetting resin or a thermosetting and light curable resin. The material for the through electrode DE exhibits anisotropic conductivity by light irradiation or thermocompression bonding. Examples of conductive particles used for the through electrode DE include particles of a spherical organic resin coated with a thin-film metal of Au, Ni, Co, or the like.

As illustrated in FIG. 27A to FIG. 27C, the terminal portion can be exposed on the rear surface side in each of the plurality of display panels. With this structure, a driver IC (integrated circuit) for driving the display panel, such as the source line driver circuit 31, can be attached on the rear surface side and connected through the through electrode in each of the plurality of display panels. That is, the driver IC can be provided on the rear side of the side where the display portion 13 is seen (the surface side) in each of the display panels.

FIG. 27D is a schematic cross-sectional view illustrating the display panels 450A and 450B as adjacent display panels. In FIG. 27D, the direction of light emitted from a displayed image is indicated by an arrow on the side where the display portion 13 is seen (the surface side).

In the display panel 450A illustrated in FIG. 27D, a region 401A transmitting visible light, a pixel circuit portion 57A, a terminal portion 14A, a driver IC 35A, and an FPC 21A are illustrated. In the display panel 450B illustrated in FIG. 27D, a region 401B transmitting visible light, a pixel circuit portion 57B, a terminal portion 14B, a driver IC 35B, and an FPC 21B are illustrated. In FIG. 27D, a through electrode is provided in each display panel, and the driver IC and the pixel circuit portion are connected to each other through the through electrode. With this structure, the driver ICs 35A and 35B, each of which corresponds to the gate line driver circuit 33 having a function of the source line driver circuit 31, can be placed in each display panel that is a divided region, whereby the display panels can be driven with different driving frequencies (e.g., frame frequencies, frame rates, or refresh rates).

The display apparatus of one embodiment of the present invention can include the gate line driver circuit and/or the source line driver circuit in each of the divided sub-display portions of the display portion. Thus, image rewriting can be performed in each of the sub-display portions. For example, in the display portion, image rewriting can be performed only in a section with an image change and image data can be retained in a section with no change, so that power consumption can be reduced.

In the display apparatus of one embodiment of the present invention, driving frequency (e.g., frame frequency, frame rate, or refresh rate) at the time of image display can be set freely for each sub-display portion. Thus, by a combination with gaze measurement (eye tracking) or the like, foveated rendering, which is a kind of drawing in which the frame rate is made different between regions in accordance with the user's gaze, can be employed. Thus, an image with excellent display quality can be output with a small load.

At least part of the structure examples, the drawings corresponding thereto, and the like described in this embodiment can be combined with the other structure examples, the other drawings, and the like as appropriate.

### Embodiment 2

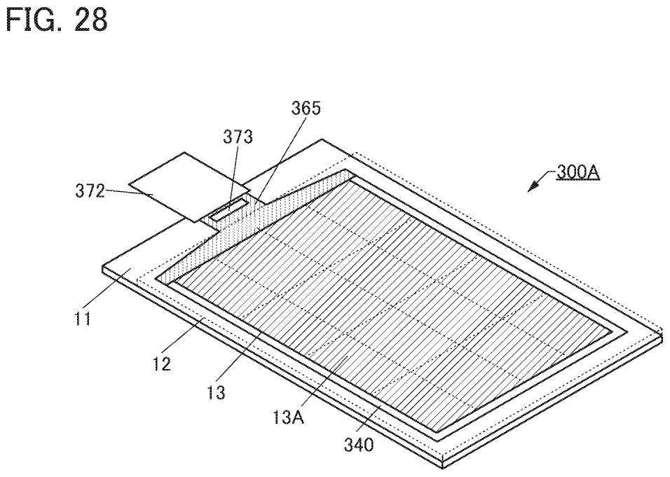

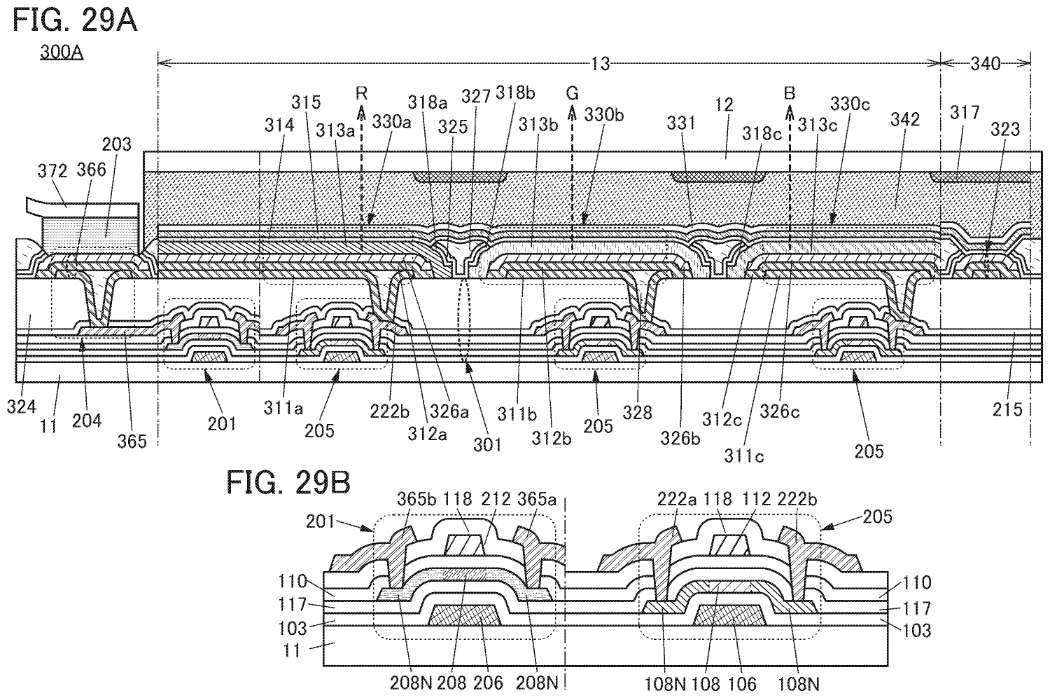

In this embodiment, a display apparatus of one embodiment of the present invention will be described with reference to FIG. 28, FIG. 29A, and FIG. 29B.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game machine, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### Display Apparatus

FIG. 28 is a perspective view of a display apparatus 300A, and FIG. 29A is a cross-sectional view of the display apparatus 300A.

The display apparatus 300A has a structure where the substrate 12 and the substrate 11 are attached to each other. In FIG. 28, the substrate 12 is denoted by a dashed line.

The display apparatus 300A includes the display portion 13, a connection portion 340, a wiring 365, and the like. The display portion 13 includes a plurality of sub-display portions 13A. FIG. 28 illustrates an example where an IC 373 and an FPC 372 are mounted on the display apparatus 300A. Thus, the structure illustrated in FIG. 28 can be regarded as a display module including the display apparatus 300A, the IC (integrated circuit), and the FPC.

The connection portion 340 is provided outside the display portion 13. The connection portion 340 can be provided along one or more sides of the display portion 13. The number of connection portions 340 can be one or more. FIG. 28 illustrates an example where the connection portion 340 is provided to surround the four sides of the display portion. A common electrode of a light-emitting device is electrically connected to a conductive layer in the connection portion 340, so that a potential can be supplied to the common electrode.

The wiring 365 has a function of supplying a signal and electric power to the display portion 13. The signal and electric power are input to the wiring 365 from the outside through the FPC 372 or input to the wiring 365 from the IC 373.

FIG. 28 illustrates an example where the IC 373 is provided over the substrate 11 by a COG method, a COF (Chip On Film) method, or the like. An IC including a scan line driver circuit or the like can be used as the IC 373, for example. Note that the display apparatus 300A and the display module are not necessarily provided with an IC. In addition, the IC may be mounted on the FPC by a COF method or the like.

FIG. 29A illustrates an example of cross sections of part of a region including the FPC 372, part of the display portion 13, 340, part of the connection portion 340, and part of a region including an end portion of the display apparatus 300A.

The display apparatus 300A illustrated in FIG. 29A includes a transistor 201, a transistor 205, a light-emitting device 330a emitting red light, a light-emitting device 330b emitting green light, a light-emitting device 330c emitting blue light, and the like between the substrate 11 and the substrate 12.

The light-emitting device 330a includes a conductive layer 311a, a conductive layer 312a over the conductive layer 311a, and a conductive layer 326a over the conductive layer 312a. All of the conductive layer 311a, the conductive layer 312a, and the conductive layer 326a can be referred to as the pixel electrode, or one or two of them can be referred to as the pixel electrode.

The conductive layer 311a is connected to a conductive layer 222b included in the transistor 205 through an opening provided in an insulating layer 324. An end portion of the conductive layer 312a is positioned outward from an end portion of the conductive layer 311a. The end portion of the conductive layer 312a and the end portion of the conductive layer 326a are aligned or substantially aligned with each other. For example, a conductive layer functioning as a reflective electrode can be used as the conductive layer 311a and the conductive layer 312a, and a conductive layer functioning as a transparent electrode can be used as the conductive layer 326a.

The light-emitting device 330b includes a conductive layer 311b, a conductive layer 312b over the conductive layer 311b, and a conductive layer 326b over the conductive layer 312b.

The light-emitting device 330c includes a conductive layer 311c, a conductive layer 312c over the conductive layer 311c, and a conductive layer 326c over the conductive layer 312c.

Detailed description of the conductive layer 311b, the conductive layer 312b, and the conductive layer 326b of the light-emitting device 330b and the conductive layer 311c, the conductive layer 312c, and the conductive layer 326c of the light-emitting device 330c is omitted because these conductive layers are similar to the conductive layer 311a, the conductive layer 312a, and the conductive layer 326a of the light-emitting device 330a.

Depressed portions are formed in the conductive layer 311a, the conductive layer 311b, and the conductive layer 311c to cover the openings provided in the insulating layer 324. A layer 328 is embedded in each of the depressed portions.

The layer 328 has a planarization function for the depressed portions of the conductive layer 311a, the conductive layer 311b, and the conductive layer 311c. Over the conductive layer 311a, the conductive layer 311b, the conductive layer 311c, and the layer 328, the conductive layer 312a, the conductive layer 312b, and the conductive layer 312c that are electrically connected respectively to the conductive layer 311a, the conductive layer 311b, and the conductive layer 311c are provided. Thus, regions overlapping with the depressed portions of the conductive layer 311a, the conductive layer 311b, and the conductive layer 311c can also be used as the light-emitting regions, increasing the aperture ratio of the pixels.

The layer 328 may be an insulating layer or a conductive layer. Any of a variety of inorganic insulating materials, organic insulating materials, and conductive materials can be used for the layer 328 as appropriate. In particular, the layer 328 is preferably formed using an insulating material.

An insulating layer containing an organic material can be suitably used as the layer 328. For the layer 328, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 328. As the photosensitive resin, a positive photosensitive material or a negative photosensitive material can be used.

When a photosensitive resin is used, the layer 328 can be formed through only light-exposure and development steps, reducing the influence of dry etching, wet etching, or the like on the surfaces of the conductive layer 311a, the conductive layer 311b, and the conductive layer 311c. When the layer 328 is formed using a negative photosensitive resin, the layer 328 can sometimes be formed using the same photomask (light-exposure mask) as the photomask used for forming the opening in the insulating layer 324.

The top surface and the side surface of the conductive layer 312a and the top surface and the side surface of the conductive layer 326a are covered with a first layer 313a. The top surface and the side surface of the conductive layer 312b and the top surface and the side surface of the conductive layer 326b are covered with a second layer 313b. Moreover, the top surface and the side surface of the conductive layer 312c and the top surface and the side surface of the conductive layer 326c are covered with a third layer 313c. Accordingly, regions provided with the conductive layer 312a, the conductive layer 312b, and the conductive layer 312c can be entirely used as the light-emitting regions of the light-emitting device 330a, the light-emitting device 330b, and the light-emitting device 330c, increasing the aperture ratio of the pixels.

The side surfaces of the first layer 313a, the second layer 313b, and the third layer 313c are covered with an insulating layer 325 and an insulating layer 327. A sacrificial layer 318a is positioned between the first layer 313a and the insulating layer 325, a sacrificial layer 318b is positioned between the second layer 313b and the insulating layer 325, and a sacrificial layer 318c is positioned between the third layer 313c and the insulating layer 325. A fourth layer 314 is provided over the first layer 313a, the second layer 313b, the third layer 313c, the insulating layer 325 and the insulating layer 327, and a common electrode 315 is provided over the fourth layer 314. The fourth layer 314 and the common electrode 315 are each one continuous film provided to be shared by a light-receiving device and the light-emitting devices. A protective layer 331 is provided over the light-emitting device 330a, the light-emitting device 330b, and the light-receiving device 330c.

The protective layer 331 and the substrate 12 are bonded to each other with an adhesive layer 342. A solid sealing structure, a hollow sealing structure, or the like can be employed to seal the light-emitting devices. In FIG. 29A, a solid sealing structure is employed in which a space between the substrate 12 and the substrate 11 is filled with the adhesive layer 342. Alternatively, a hollow sealing structure may be employed, in which the space is filled with an inert gas (e.g., nitrogen or argon). The adhesive layer 342 may be provided not to overlap with the light-emitting device. The space may be filled with a resin different from that of the frame-like adhesive layer 342.

A conductive layer 323 is provided over the insulating layer 324 in the connection portion 340. An example is described in which the conductive layer 323 has a stacked-layer structure of a conductive film obtained by processing the same conductive film as the conductive layer 311a, the conductive layer 311b, and the conductive layer 311c; a conductive film obtained by processing the same conductive film as the conductive layer 312a, the conductive layer 312b, and the conductive layer 312c; and a conductive film obtained by processing the same conductive film as the conductive layer 326a, the conductive layer 326b, and the conductive layer 326c. The end portion of the conductive layer 323 is covered with the sacrificial layer, the insulating layer 325, and the insulating layer 327. The fourth layer 314 is provided over the conductive layer 323, and the common electrode 315 is provided over the fourth layer 314. The conductive layer 323 and the common electrode 315 are electrically connected to each other through the fourth layer 314. Note that the fourth layer 314 is not necessarily formed in the connection portion 340. In that case, the conductive layer 323 and the common electrode 315 are in direct contact with each other to be electrically connected to each other.

The display apparatus 300A is of a top-emission type. Light emitted by the light-emitting device is emitted toward the substrate 12 side. For the substrate 12, a material having a high visible-light-transmitting property is preferably used. The pixel electrode contains a material reflecting visible light, and a counter electrode (the common electrode 315) contains a material transmitting visible light.

An insulating layer 215 is provided to cover the transistors. The insulating layer 324 is provided to cover the transistors and has a function of a planarization layer. Note that there is no limitation on the number of insulating layers covering the transistors, and either a single layer or two or more layers may be employed.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of the display apparatus.

An inorganic insulating film is preferably used for the insulating layer 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating film can be suitably used for the insulating layer 324 functioning as the planarization layer. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 324 may have a stacked-layer structure of an organic insulating film and an inorganic insulating film. The outermost layer of the insulating layer 324 preferably functions as an etching protective film. In that case, formation of a depressed portion in the insulating layer 324 can be inhibited in processing of the conductive layer 311b, the conductive layer 312b, the conductive layer 326b, or the like. Alternatively, a depressed portion may be provided in the insulating layer 324 in processing the conductive layer 311b, the conductive layer 312b, the conductive layer 326b, or the like.

A connection portion 204 is provided in a region of the substrate 11 not overlapping with the substrate 12. In the connection portion 204, the wiring 365 is electrically connected to the FPC 372 through a conductive layer 366 and a connection layer 203. An example is described where the conductive layer 366 has a stacked-layer structure of a conductive film obtained by processing the same conductive film as the conductive layer 311a, the conductive layer 311b, and the conductive layer 311c; a conductive film obtained by processing the same conductive film as the conductive layer 312a, the conductive layer 312b, and the conductive layer 312c; and a conductive film obtained by processing the same conductive film as the conductive layer 326a, the conductive layer 326b, and the conductive layer 326c. On the top surface of the connection portion 204, the conductive layer 366 is exposed. Thus, the connection portion 204 and the FPC 372 can be electrically connected to each other through the connection layer 203.

A light-blocking layer 317 is preferably provided on the surface of the substrate 12 on the substrate 11 side. The light-blocking layer 317 can be provided between adjacent light-emitting devices and in the connection portion 340, for example. Moreover, a variety of optical members can be provided on the outer surface of the substrate 12. Examples of the optical members include a polarizing plate, a retardation plate, a light diffusion layer (e.g., a diffusion film), an anti-reflective layer, and a light-condensing film. Furthermore, an antistatic film inhibiting attachment of dust, a water repellent film inhibiting attachment of stain, a hard coat film inhibiting generation of a scratch caused by the use, an impact-absorbing layer, or the like may be arranged on the outer side of the substrate 12.

The protective layer 331 provided to cover the light-emitting devices and the light-receiving device can inhibit an impurity such as water from entering the light-emitting devices and the light-receiving device, and increase the reliability of the light-emitting devices and the light-receiving device.

For each of the substrate 11 and the substrate 12, glass, quartz, ceramics, sapphire, a resin, a metal, an alloy, a semiconductor, or the like can be used. For the substrate through which light from the light-emitting device is extracted, a material transmitting the light is used. When a material having flexibility is used for the substrate 11 and the substrate 12, the flexibility of the display apparatus can be increased. Furthermore, a polarizing plate may be used as the substrate 11 or the substrate 12.

For each of the substrate 11 and the substrate 12, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrate 11 and the substrate 12.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of a display panel might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the adhesive layer 342, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. Alternatively, an adhesive sheet or the like may be used.

For the connection layer 203, ACF, ACP, or the like can be used.

As examples of the materials that can be used for the gate, the source, and the drain of the transistor and conductive layers such as a variety of wirings and electrodes included in the display apparatus, metals such as aluminum, titanium, chromium, nickel, copper, yttrium, zirconium, molybdenum, silver, tantalum, and tungsten, and an alloy containing any of these metals as its main component can be given. A single layer or a stacked-layer structure including a film containing any of these materials can be used.

As a conductive material having a light-transmitting property, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is preferably made thin enough to have a light-transmitting property. Furthermore, a stacked-layer film of the above materials can be used for a conductive layer. For example, a stacked-layer film of indium tin oxide and an alloy of silver and magnesium is preferably used because conductivity can be increased. These materials can also be used for conductive layers such as a variety of wirings and electrodes included in the display apparatus, and conductive layers (a conductive layer functioning as a pixel electrode or a common electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### <Transistor>

FIG. 29B is an enlarged view of a cross section including the transistor 201 and the transistor 205.

The transistor 205 includes a semiconductor layer 108, an insulating layer 117, an insulating layer 110, and a conductive layer 112 that are stacked in this order. Parts of the insulating layer 117 and the insulating layer 110 function as gate insulating layers of the transistor 201. The conductive layer 112 functions as the gate electrode of the transistor 201. The transistor 201 is what is called a top-gate transistor, in which the gate electrode is provided over the semiconductor layer 108.

The transistor 201 includes a semiconductor layer 208, the insulating layer 110, and a conductive layer 212 that are stacked in this order. Part of the insulating layer 110 functions as a gate insulating layer of the transistor 205. The conductive layer 212 functions as a gate electrode of the transistor 205. The transistor 205 is what is called a top-gate transistor, in which the gate electrode is provided over the semiconductor layer 208. The transistor 205 is different from the transistor 201 in the formation surface of the semiconductor layer. Furthermore, the transistor 205 is different from the transistor 201 in the structure of the gate insulating layer.

The components of the transistor 201 and the transistor 205 other than their semiconductor layers can be formed in the same steps. This can inhibit an increase in the number of steps even when two types of transistors are incorporated.

The transistor 205 illustrated in FIG. 29B includes a conductive layer 106 functioning as a back gate. In addition, the transistor 201 illustrated in FIG. 29B includes a conductive layer 206 functioning as a back gate.

In FIG. 29B, the conductive layer 106 is provided over and in contact with the substrate 11. An insulating layer 103 is provided over and in contact with the conductive layer 106 and the substrate 11. The conductive layer 108 is provided over and in contact with the insulating layer 103. The insulating layer 117 is provided in contact with the top surfaces of the insulating layer 103 and the substrate 11 and the top surface and the side surface of the semiconductor layer 108. The semiconductor layer 208 is provided over and in contact with the insulating layer 117. In other words, the semiconductor layer 208 and the semiconductor layer 108 are provided on different planes. The insulating layer 117 functions as a base film in the transistor 201. The insulating layer 110 is provided in contact with the top surface of the insulating layer 117 and the top and side surfaces of the semiconductor layer 208. The conductive layer 112 and the conductive layer 212 are provided over and in contact with the insulating layer 110. The conductive layer 112 includes a region overlapping with the semiconductor layer 108 with the insulating layer 117 and the insulating layer 110 therebetween. The conductive layer 212 includes a region overlapping with the semiconductor layer 208 with the insulating layer 110 therebetween.

Preferably, the transistor 201 and the transistor 205 further include an insulating layer 118, as illustrated in FIG. 29B. The insulating layer 118 is provided to cover the insulating layer 110, the conductive layer 112, and the conductive layer 212 and functions as a protective layer protecting the transistor 201 and the transistor 205.

The transistor 205 may include a conductive layer 222a and the conductive layer 222b over the insulating layer 118. The conductive layer 222a functions as one of a source electrode and a drain electrode of the transistor 205, and the conductive layer 222b functions as the other of the source electrode and the drain electrode of the transistor 205. The conductive layer 222a and the conductive layer 222b are electrically connected to low-resistance regions 108N included in the semiconductor layer 108 through opening portions provided in the insulating layer 118, the insulating layer 110, and the insulating layer 117.

The transistor 201 may include a conductive layer 365a and a conductive layer 365b over the insulating layer 118. The conductive layer 365a functions as one of a source electrode and a drain electrode of the transistor 201, and the conductive layer 365b functions as the other of the source electrode and the drain electrode of the transistor 201. The conductive layer 365a and the conductive layer 365b are electrically connected to low-resistance regions 208N included in the semiconductor layer 208 through opening portions provided in the insulating layer 118 and the insulating layer 110.

Here, the semiconductor layer 108 and the semiconductor layer 208 preferably include metal oxides having different compositions. The semiconductor layer 108 and the semiconductor layer 208 can be formed by processing metal oxide films having different compositions. The display apparatus of one embodiment of the present invention includes, over the same substrate, a plurality of transistors whose semiconductor layers have different compositions, and the components other than the semiconductor layers can be formed in the same steps.

As described above, electrical characteristics and reliability of a transistor vary depending on the composition of the metal oxide used for the semiconductor layer. Therefore, by determining the composition of the metal oxide in accordance with the electrical characteristics and reliability required for the transistor, the display apparatus can have both excellent electrical characteristics and high reliability.

The case where the transistor 201 is used as a transistor required to have a high on-state current is described as an example. In the case where an In-Ga-Zn oxide is used for both the semiconductor layer 108 and the semiconductor layer 208, the semiconductor layer 208 can be formed using a metal oxide having a higher atomic ratio of indium to the contained metal elements than a metal oxide used in the semiconductor layer 108, for example. The semiconductor layer 108 can be formed using a metal oxide having a higher atomic ratio of gallium to the contained metal elements than a metal oxide used in the semiconductor layer 208, for example.

Also in the case where an In-Ga-Zn oxide is used for the semiconductor layer 108 and a metal oxide containing indium, other than the In-Ga-Zn oxide, is used for the semiconductor layer 208, the semiconductor layer 208 can be formed using a metal oxide having a higher atomic ratio of indium to the metal elements than a metal oxide used in the semiconductor layer 108.

A metal oxide containing indium, other than the In-Ga-Zn oxide, can also be used for the semiconductor layer 108. Also in that case, the semiconductor layer 208 can be formed using a metal oxide having a higher atomic ratio of indium to the metal elements than a metal oxide used in the semiconductor layer 108.

Alternatively, the semiconductor layer 108 may be formed using a metal oxide having a higher atomic ratio of indium to the contained metal elements than a metal oxide used in the semiconductor layer 208.

The semiconductor layer 108 includes a region overlapping with the conductive layer 112 and a pair of low-resistance regions 108N between which the region is interposed. A region of the semiconductor layer 108 overlapping with the conductive layer 112 functions as a channel formation region of the transistor 205. The pair of low-resistance regions 108N function as a source region and a drain region of the transistor 205. The semiconductor layer 208 similarly includes a channel formation region overlapping with the conductive layer 212 and a pair of low-resistance regions 208N between which the region is interposed.

In the transistor 205, the low-resistance region 108N can be regarded as a region having lower resistance than the channel formation region of the transistor 205, a region having a higher carrier concentration than the channel formation region, a region having a higher density of oxygen vacancy than the channel formation region, a region having a higher impurity concentration than the channel formation region, or an n-type region. Also in the transistor 201, the low-resistance region 208N can be regarded as a region having lower resistance than the channel formation region of the transistor 201, a region having a higher carrier concentration than the channel formation region, a region having a higher density of oxygen vacancy than the channel formation region, a region having a higher impurity concentration than the channel formation region, or an n-type region.

Each of the low-resistance region 108N and the low-resistance region 208N is a region containing an impurity element. Examples of the impurity element include hydrogen, boron, carbon, nitrogen, fluorine, phosphorus, sulfur, arsenic, aluminum, and a noble gas. Note that typical examples of a noble gas include helium, neon, argon, krypton, and xenon. In particular, the low-resistance region 108N and the low-resistance region 208N preferably contain boron or phosphorus. The low-resistance region 108N and the low-resistance region 208N may contain two or more of the elements described above. Note that the low-resistance region 108N and the low-resistance region 208N may contain different impurity elements.

The low-resistance region 108N and the low-resistance region 208N can be formed by, for example, addition of an impurity through the insulating layer 110 using the conductive layer 112 and the conductive layer 212, respectively, as masks.

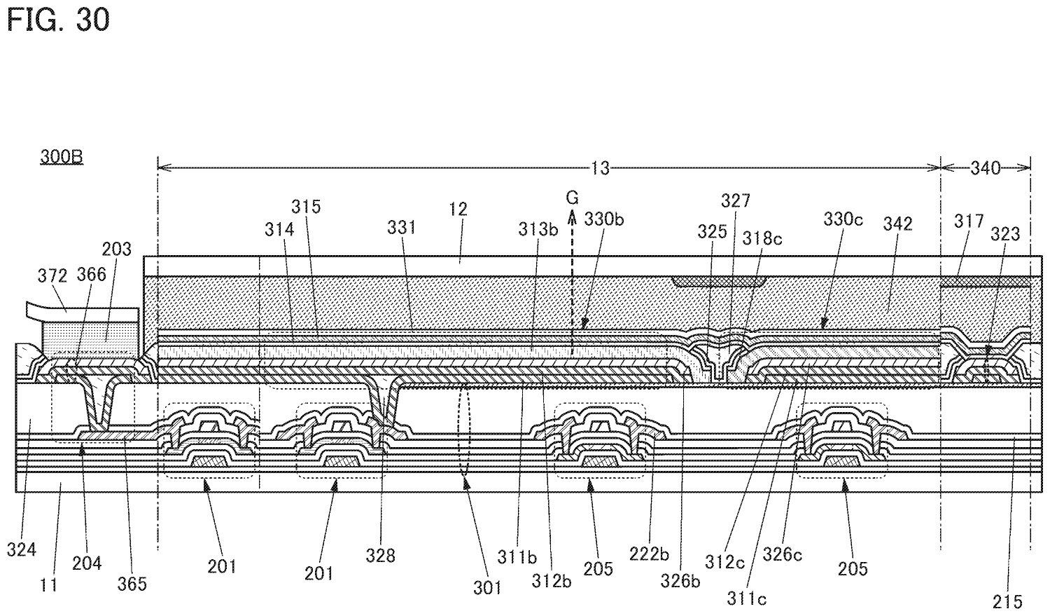

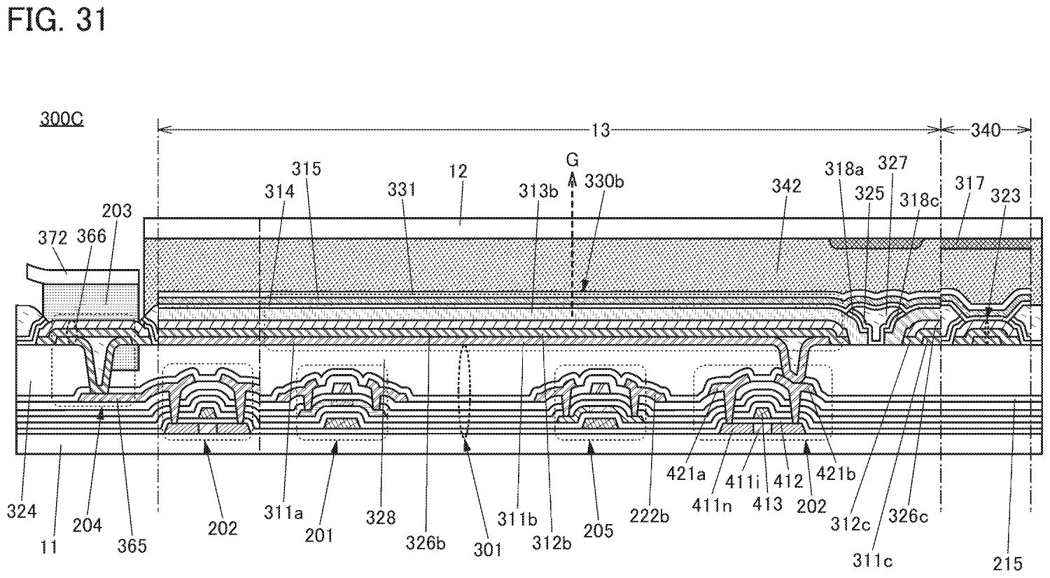

A display apparatus 300B illustrated in FIG. 30 shows an example where the transistor 201 and the transistor 205 are used as the transistors included in the display portion 13. When the pixel circuit included in the display portion 13 includes the transistor 201 and the transistor 205, a display apparatus with high display quality and high reliability can be achieved. The fabrication process of the display apparatus can be simpler than that of FIG. 31 described later.

A display apparatus 300C illustrated in FIG. 31 shows an example where the transistor 201, the transistor 205, and a transistor 202 are used as the transistors included in the display portion 13. When the pixel circuit included in the display portion 13 includes the transistor 201, the transistor 202, and the transistor 205, a display apparatus with high display quality and high reliability can be achieved.

The transistor 202 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. For example, LTPS can be used as polycrystalline silicon. Part of the insulating layer 412 functions as a gate insulating layer. Part of the conductive layer 413 functions as a gate electrode.

A low-resistance region 31 In is a region containing an impurity element. For example, in the case where the transistor 202 is an n-channel transistor, phosphorus, arsenic, or the like is added to the low-resistance region 311n. Meanwhile, in the case where the transistor 202 is a p-channel transistor, boron, aluminum, or the like is added to the low-resistance region 311n. In addition, in order to control the threshold voltage of the transistor 202, the above-described impurity may be added to the channel formation region 311i.

The transistor 202 may include a conductive layer 421a and a conductive layer 421b over the insulating layer 118. The conductive layer 421a functions as one of a source electrode and a drain electrode of the transistor 202, and the conductive layer 421b functions as the other of the source electrode and the drain electrode of the transistor 202. The conductive layer 421a and the conductive layer 421b are each electrically connected to the low-resistance region 411n through an opening portion provided in the insulating layer 118, the insulating layer 110, the insulating layer 117, and the insulating layer 412.

Here, the conductive layer 421a and the conductive layer 421b that are electrically connected to the transistor 202 are preferably formed by processing the same conductive film as the conductive layer 222a, the conductive layer 222b, the conductive layer 365a, and the conductive layer 365b. This is preferable because the fabrication process can be simplified.

The conductive layer 413 functioning as the gate electrode of the transistor 202, the conductive layer 206 functioning as the second gate electrode of the transistor 201, and the conductive layer 106 functioning as the second gate of the transistor 205 are preferably formed by processing the same conductive film. This is preferable because the fabrication process can be simplified.

Note that the transistor 202 may include a second gate electrode. In the case where the transistor 202 includes the second gate electrode, for example, a conductive layer functioning as the second gate electrode is provided over the substrate 11, an insulating layer is provided in contact with the top surfaces of the conductive layer and the substrate 11, and the semiconductor layer 411 is provided over the insulating layer. In addition, the conductive layer 413 and the conductive layer functioning as the second gate electrode preferably have a region where they overlap with each other.

At least part of this embodiment can be implemented in appropriate combination with the other embodiments described in this specification.

### Embodiment 3

In this embodiment, a light-emitting device that can be used for a display apparatus of one embodiment of the present invention will be described.

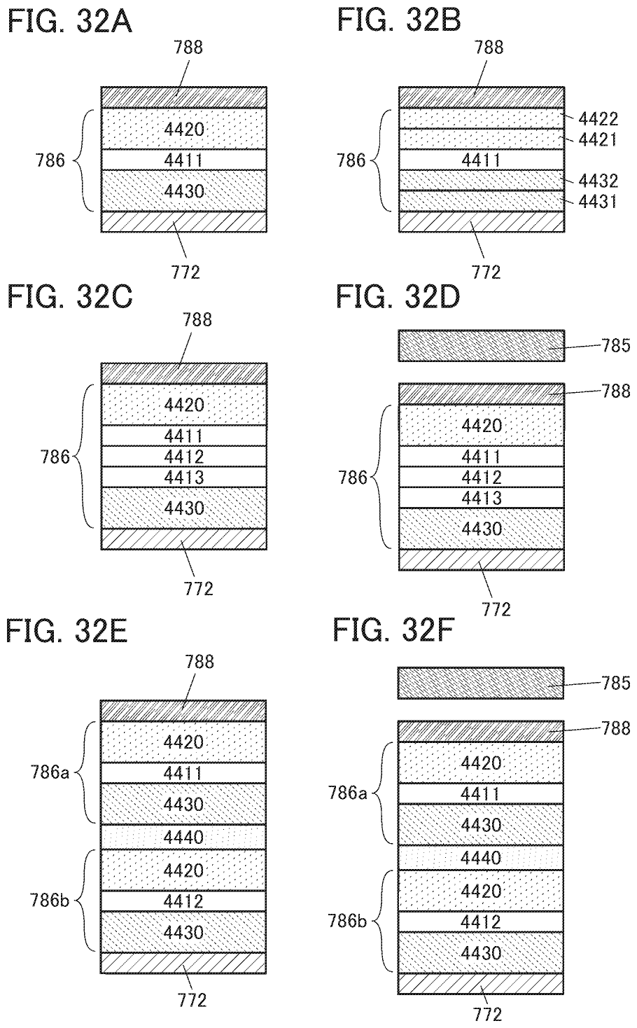

As illustrated in FIG. 32A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can serve as a single light-emitting unit, and the structure in FIG. 32A is referred to as a single structure in this specification.

FIG. 32B is a variation example of the EL layer 786 included in the light-emitting device illustrated in FIG. 32A. Specifically, the light-emitting device illustrated in FIG. 32B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. In the case where the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, in the case where the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that the structure where a plurality of light-emitting layers (light-emitting layers 4411, 4412, and 4413) are provided between the layer 4420 and the layer 4430 as illustrated in FIG. 32C and FIG. 32D is also a variation of the single structure.

A structure where a plurality of light-emitting units (an EL layer 786a and an EL layer 786b) are connected in series with a charge-generation layer 4440 therebetween as illustrated in FIG. 32E and FIG. 32F is referred to as a tandem structure in this specification. Note that the tandem structure may be referred to as a stack structure. The tandem structure enables a light-emitting device capable of high luminance light emission.

In FIG. 32C and FIG. 32D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 32D. Note that a color conversion layer with a structure using quantum dots enables a light-emitting device to have excellent color purity and favorable external quantum efficiency.

Light-emitting materials with different emission colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 32D. When white light passes through a color filter, light of a desired color can be obtained.

In FIG. 32E and FIG. 32F, light-emitting materials that emit light of the same color, or moreover, the same light-emitting material may be used for the light-emitting layer 4411 and the light-emitting layer 4412. Alternatively, light-emitting materials with different emission colors may be used for the light-emitting layer 4411 and the light-emitting layer 4412. White light emission can be obtained when the light-emitting layer 4411 and the light-emitting layer 4412 emit light of complementary colors. FIG. 32F illustrates an example where the layer 785 is further provided. One or both of a color conversion layer and a color filter (coloring layer) can be used as the layer 785.

In FIG. 32C, FIG. 32D, FIG. 32E, and FIG. 32F, the layer 4420 and the layer 4430 may each have a stacked-layer structure of two or more layers as in FIG. 32B.

A structure where light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, white, or the like depending on the material that constitutes the EL layer 786. In addition, when the light-emitting device has a microcavity structure, color purity can be further increased.

The light-emitting device that emits white light preferably contains two or more kinds of light-emitting substances in the light-emitting layer. To obtain white light emission, two or more kinds of light-emitting substances are selected such that they emit light of complementary colors. For example, when the emission color of a first light-emitting layer and the emission color of a second light-emitting layer are complementary colors, it is possible to obtain a light-emitting device that emits white light as a whole. The same applies to a light-emitting device including three or more light-emitting layers.

The light-emitting layer preferably contains two or more selected from light-emitting substances that emit light of red (R), green (G), blue (B), yellow (Y), orange (O), and the like. Alternatively, the light-emitting layer preferably contains two or more light-emitting substances that emit light containing two or more of spectral components of R, G, and B.

This embodiment can be combined with the other embodiments as appropriate.

### Embodiment 4

In this embodiment, electronic devices each including a display apparatus fabricated using one embodiment of the present invention will be described.

Electronic devices described below as examples each include the display apparatus of one embodiment of the present invention in a display portion. Thus, the electronic devices achieve high definition. In addition, the electronic devices can each achieve both high definition and a large screen.

A display portion in an electronic device of one embodiment of the present invention can display a video with a definition of, for example, full high definition, 4K2K, 8K4K, 16K8K, or higher.

Examples of the electronic devices include a digital camera, a digital video camera, a digital photo frame, a mobile phone, a portable game machine, a portable information terminal, and an audio reproducing device, in addition to electronic devices with comparatively large screens, such as a television device, a notebook personal computer, a monitor device, digital signage, a pachinko machine, and a game machine.

An electronic device using one embodiment of the present invention can be incorporated along a flat surface or a curved surface of an inside wall or an outside wall of a house or a building, an interior or an exterior of a car, or the like.

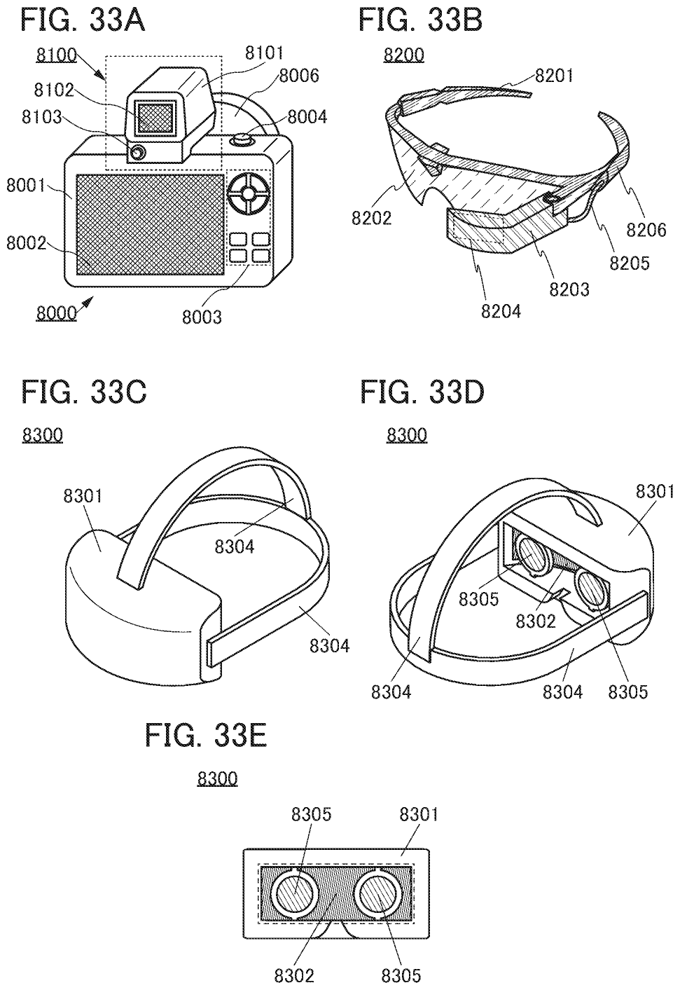

FIG. 33A is a diagram illustrating the appearance of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000.

Note that the lens 8006 and the housing may be integrated with each other in the camera 8000

Images can be taken with the camera 8000 at the press of the shutter button 8004 or the touch of the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 by a mount for engagement with the mount of the camera 8000. In the finder 8100, a video or the like received from the camera 8000 can be displayed on the display portion 8102.

The button 8103 functions as a power button or the like.

The display apparatus of one embodiment of the present invention can be used for the display portion 8002 of the camera 8000 and the display portion 8102 of the finder 8100. Note that a finder may be incorporated in the camera 8000.

FIG. 33B is a diagram illustrating the appearance of a head-mounted display 8200.

The head-mounted display 8200 includes a wearing portion 8201, a lens 8202, a main body 8203, a display portion 8204, a cable 8205, and the like. In addition, a battery 8206 is incorporated in the wearing portion 8201.

The cable 8205 supplies power from the battery 8206 to the main body 8203. The main body 8203 includes a wireless receiver or the like and can display received video information on the display portion 8204. In addition, the main body 8203 is provided with a camera, and information on the movement of the user's eyeball or eyelid can be used as an input means.

The wearing portion 8201 may be provided with a plurality of electrodes capable of detecting current flowing in response to the movement of the user's eyeball in a position in contact with the user to have a function of recognizing the user's gaze. The wearing portion 8201 may also have a function of monitoring the user's pulse with the use of current flowing through the electrodes. Moreover, the wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, or the like.

The display apparatus of one embodiment of the present invention can be used in the display portion 8204.

FIG. 33C, FIG. 33D, and FIG. 33E are diagrams illustrating the appearance of a head-mounted display 8300. The head-mounted display 8300 includes a housing 8301, a display portion 8302, a band-like fixing member 8304, and a pair of lenses 8305.

A user can see display on the display portion 8302 through the lenses 8305. Note that the display portion 8302 is preferably curved and placed because the user can feel a high realistic sensation. Another image displayed in another region of the display portion 8302 is seen through the lenses 8305, so that three-dimensional display using parallax or the like can be performed. Note that the structure is not limited to the structure where one display portion 8302 is provided; two display portions 8302 may be provided and one display portion may be provided per eye of the user.

The display apparatus of one embodiment of the present invention can be used in the display portion 8302. A display apparatus including a semiconductor device of one embodiment of the present invention has an extremely high resolution; thus, even when an image is magnified using the lenses 8305 as in FIG. 33E, the user does not perceive pixels, and thus a more realistic image can be displayed.

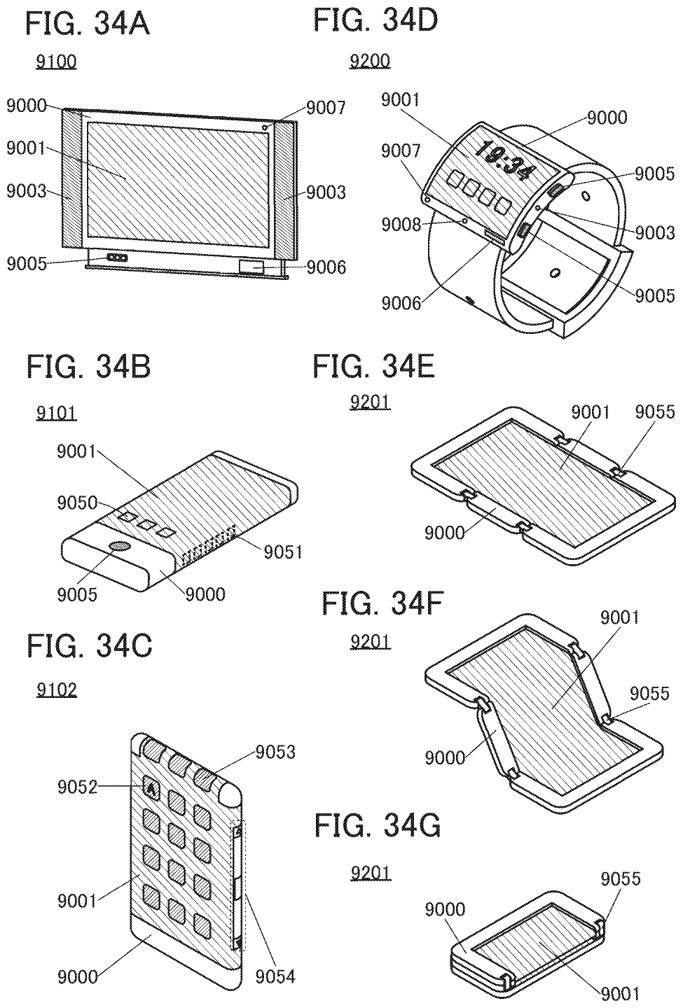

Electronic devices illustrated in FIG. 34A to FIG. 34G include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 34A to FIG. 34G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The details of the electronic devices illustrated in FIG. 34A to FIG. 34G are described below.

FIG. 34A is a perspective view illustrating a television device 9100. The display portion 9001 having a large screen size of, for example, 50 inches or more, or 100 inches or more can be incorporated in the television device 9100.

FIG. 34B is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display text or image information on its plurality of surfaces. FIG. 34B illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the reception strength of an antenna. Alternatively, the icon 9050 or the like may be displayed at the position where the information 9051 is displayed.

FIG. 34C is a perspective view illustrating a portable information terminal 9102. The portable information terminal 9102 has a function of displaying information on three or more surfaces of the display portion 9001. Shown here is an example where information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 34D is a perspective view illustrating a watch-type portable information terminal 9200. The display surface of the display portion 9001 is curved, and an image can be displayed on the curved display surface. Furthermore, intercommunication between the portable information terminal 9200 and, for example, a headset capable of wireless communication enables hands-free calling. Moreover, with the connection terminal 9006, the portable information terminal 9200 can also perform mutual data transmission with another information terminal or charging. Note that the charging operation may be performed by wireless power feeding.

FIG. 34E, FIG. 34F, and FIG. 34G are perspective views illustrating a foldable portable information terminal 9201. FIG. 34E is a perspective view of an opened state of the portable information terminal 9201, FIG. 34G is a perspective view of a folded state thereof, and FIG. 34F is a perspective view of a state in the middle of change from one of FIG. 34E and FIG. 34G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 1 mm and less than or equal to 150 mm.

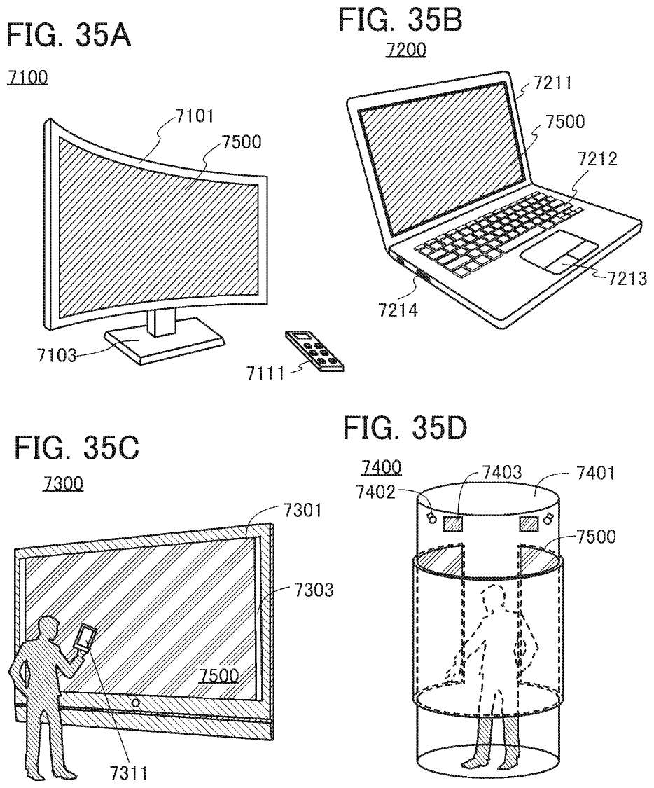

FIG. 35A illustrates an example of a television device. In a television device 7100, a display portion 7500 is incorporated in a housing 7101. Here, a structure where the housing 7101 is supported by a stand 7103 is illustrated.

Operation of the television device 7100 illustrated in FIG. 35A can be performed not only with an operation switch provided in the housing 7101 but also with a separate remote controller 7111. Alternatively, a touch panel may be used for the display portion 7500, and the television device 7100 may be operated by touch on the touch panel. The remote controller 7111 may include a display portion in addition to operation buttons.

Note that the television device 7100 may include not only a television receiver but also a communication device for network connection.

FIG. 35B illustrates a notebook personal computer 7200. A notebook personal computer 7200 includes a housing 7211, a keyboard 7212, a pointing device 7213, an external connection port 7214, and the like. The display portion 7500 is incorporated in the housing 7211.

FIG. 35C illustrates an example of digital signage.

Digital signage 7300 illustrated in FIG. 35C includes a housing 7301, the display portion 7500, a speaker 7303, and the like. The digital signage 7300 can also include an LED lamp, an operation key (including a power switch or an operation switch), a connection terminal, a variety of sensors, a microphone, and the like.

The larger display portion 7500 can increase the amount of information that can be provided at a time and attracts more attention, so that the effectiveness of the advertisement can be increased, for example.

A touch panel is preferably used for the display portion 7500 so that the user can operate the digital signage. Thus, the digital signage can be used not only for advertising but also for providing information that the user needs, such as route information, traffic information, or guidance information on a commercial facility.

As illustrated in FIG. 35C, the digital signage 7300 is preferably capable of working with an information terminal 7311 such as a user's smartphone through wireless communication. For example, not only displaying information of an advertisement displayed on the display portion 7500 on a screen of the information terminal 7311 but also switching display on the display portion 7500 by operation of the information terminal 7311 is possible.

It is possible to make the digital signage 7300 execute a game with use of the information terminal 7311 as an operation means (controller). Thus, an unspecified number of users can join in and enjoy the game concurrently.

In addition, FIG. 35D is digital signage 7400 attached to an inner wall 7401 of a cylindrical space. The digital signage 7400 includes, in addition to the display portion 7500 provided along a curved surface of the inner wall 7401, a plurality of imaging devices 7402 and a plurality of audio devices 7403. Furthermore, the digital signage 7400 can perform the user's gaze measurement (eye tracking) or sense a gesture or the like by the plurality of imaging devices 7402, which allows the display portion 7500 and the audio device 7403 to operate in accordance with the user's gaze. For example, when the user turns his or her gaze toward advertising information displayed on the display portion 7500, display on the display portion 7500 can be switched and sound of the audio device 7403 can be switched, for example. Thus, the user can enjoy display, sound, and the like with excellent realistic sensation.

The display apparatus of one embodiment of the present invention can be used in the display portion 7500 in FIG. 35A to FIG. 35D.

At least part of this embodiment can be implemented in appropriate combination with the other embodiments described in this specification.

(Supplementary Notes on Description in this Specification and the Like)

The following are notes on the description of the structures in the foregoing embodiments and the structures in the embodiments.

One embodiment of the present invention can be constituted by appropriately combining the structure described in an embodiment with any of the structures described in the other embodiments. In addition, in the case where a plurality of structure examples are described in one embodiment, some of the structure examples can be combined as appropriate.

Note that a content (or part thereof) described in one embodiment can be applied to, combined with, or replaced with another content (or part thereof) described in the embodiment and/or a content (or part thereof) described in another embodiment or other embodiments, for example.

Note that in each embodiment, a content described in the embodiment is a content described using a variety of diagrams or a content described with text disclosed in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In this specification and the like, components are classified according to their functions, and illustrated as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, the blocks in the block diagrams are not limited by the components described in the specification, and the description can be changed appropriately depending on the situation.

In drawings, the size, the layer thickness, or the region is illustrated arbitrarily for description convenience. Therefore, the size, the layer thickness, or the region is not limited to the illustrated scale. Note that the drawings are schematically shown for clarity, and embodiments of the present invention are not limited to shapes, values, or the like illustrated in the drawings. For example, variations in a signal, a voltage, or a current due to noise, variations in a signal, a voltage, or a current due to difference in timing, or the like can be included.

In this specification and the like, the terms “one of a source and a drain” (or a first electrode or a first terminal) and “the other of the source and the drain” (or a second electrode or a second terminal) are used to describe the connection relationship of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In addition, in this specification and the like, the term “electrode” or “wiring” does not limit a function of the component. For example, an “electrode” is used as part of a “wiring” in some cases, and vice versa. Furthermore, for example, the term “electrode” or “wiring” also includes the case where a plurality of “electrodes” or “wirings” are formed in an integrated manner.

In this specification and the like, voltage and potential can be replaced with each other as appropriate. Voltage refers to a potential difference from a reference potential, and when the reference potential is a ground potential, for example, voltage can be replaced with potential. The ground potential does not necessarily mean 0V. Potentials are relative values, and a potential supplied to a wiring or the like is sometimes changed depending on the reference potential.

In this specification and the like, the terms “film” and “layer” can be interchanged with each other depending on the case or circumstances. For example, the term “conductive layer” can be replaced with the term “conductive film” in some cases. For another example, the term “insulating film” can be replaced with the term “insulating layer” in some cases.

In this specification and the like, a switch is in a conduction state (on state) or in a non-conduction state (off state) to determine whether current flows therethrough or not. Alternatively, a switch has a function of selecting and changing a current path.

In this specification and the like, the channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, the channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

### REFERENCE NUMERALS

11: substrate, 12: substrate, 13A: sub-display portion, 13: display portion, 14: terminal portion, 20: layer, 30: driver circuit portion, 31: source line driver circuit, 33: gate line driver circuit, 34: pulse output circuit, 39: section, 40: source line driver circuit, 41: control circuit, 50: layer, 51: pixel circuit, 55A: transistor, 55B: transistor, 55C: transistor, 55D: transistor, 57: pixel circuit portion, 56A: capacitor, 56: capacitor, 59: section, 60: layer, 61: display element

1. A display apparatus comprising a display portion where a first transistor and a display element are provided to be stacked,
wherein the display portion comprises a first sub-display portion and a second sub-display portion,
wherein the first sub-display portion and the second sub-display portion each comprise a plurality of pixel circuits each controlling the display element and a gate line driver circuit outputting a signal for driving the plurality of pixel circuits,
wherein the gate line driver circuit and the plurality of pixel circuits each comprise the first transistor, and
wherein in the display portion, the number of image rewriting times per unit time for image data in the first sub-display portion is smaller than the number of image rewriting times per unit time for image data in the second sub-display portion.

2. The display apparatus according to claim 1, wherein the first transistor comprises a metal oxide in a semiconductor layer comprising a channel formation region.

3. A display apparatus comprising a display portion where a first layer comprising a first transistor, a second layer comprising a second transistor, and a display element are provided to be stacked,
wherein the display portion comprises a first sub-display portion and a second sub-display portion,
wherein the first sub-display portion and the second sub-display portion each comprise a plurality of pixel circuits each controlling the display element and a gate line driver circuit outputting a signal for driving the plurality of pixel circuits,
wherein the gate line driver circuit comprises the first transistor and the second transistor,
wherein the plurality of pixel circuits each comprise the first transistor and the second transistor, and
wherein in the display portion, the number of image rewriting times per unit time for image data in the first sub-display portion is smaller than the number of image rewriting times per unit time for image data in the second sub-display portion.

4. A display apparatus comprising a display portion where a first layer comprising a first transistor, a second layer comprising a second transistor, and a display element are provided to be stacked,
wherein the display portion comprises a first sub-display portion and a second sub-display portion,
wherein the first sub-display portion and the second sub-display portion each comprise a plurality of pixel circuits each controlling the display element and a gate line driver circuit outputting a signal for driving the plurality of pixel circuits,
wherein the gate line driver circuit comprises the first transistor and the second transistor,
wherein the plurality of pixel circuits each comprise the first transistor and the second transistor,
wherein the second transistor comprises a metal oxide in a semiconductor layer comprising a channel formation region, and
wherein in the display portion, the number of image rewriting times per unit time for image data in the first sub-display portion is smaller than the number of image rewriting times per unit time for image data in the second sub-display portion.

5. The display apparatus according to claim 3,
wherein the first transistor comprises silicon in a semiconductor layer comprising a channel formation region.

6. The display apparatus according to claim 3, wherein the first transistor comprises a metal oxide in a semiconductor layer comprising a channel formation region.

7. The display apparatus according to claim 1, wherein a source line driver circuit is provided in a region outside the display portion.

8. A display apparatus comprising a display portion where a first layer comprising a first transistor and a display element are provided to be stacked,
wherein the display portion comprises a first sub-display portion and a second sub-display portion,
wherein the first sub-display portion and the second sub-display portion are provided in different display panels,
wherein the display panels each comprise a pixel circuit portion and a light-transmitting region, and
wherein the light-transmitting region of one of the display panels comprises a region overlapping with the pixel circuit portion of the other of the display panels.

9. An electronic device comprising the display apparatus according to claim 1 and a housing.

10. The display apparatus according to claim 4, wherein the first transistor comprises silicon in a semiconductor layer comprising a channel formation region.

11. The display apparatus according to claim 4, wherein the first transistor comprises a metal oxide in a semiconductor layer comprising a channel formation region.

12. The display apparatus according to claim 2, wherein a source line driver circuit is provided in a region outside the display portion.

13. The display apparatus according to claim 3, wherein a source line driver circuit is provided in a region outside the display portion.

14. The display apparatus according to claim 4, wherein a source line driver circuit is provided in a region outside the display portion.

15. The display apparatus according to claim 5, wherein a source line driver circuit is provided in a region outside the display portion.

16. The display apparatus according to claim 6, wherein a source line driver circuit is provided in a region outside the display portion.

17. An electronic device comprising the display apparatus according to claim 3 and a housing.

18. An electronic device comprising the display apparatus according to claim 4 and a housing.

19. An electronic device comprising the display apparatus according to claim 8 and a housing.
